(19) United States
(12) Patent Application Publication
(10) Pub. No.: US 2026/0013255 A1
(43) Pub. Date: Jan. 8, 2026

(54) OPTICAL FILTER DEVICE AND IMAGE SENSOR INCLUDING THE SAME

(71) Applicant: Samsung Electronics Co., Ltd., Suwon-si (KR)

(72) Inventors: Sunwook Kim, Suwon-si (KR); Jonghoon Park, Suwon-si (KR); Junhyeok Jang, Suwon-si (KR); Chulsoo Choi, Suwon si (KR)

(21) Appl. No.: 19/257,021

(22) Filed: Jul. 1, 2025

(30) Foreign Application Priority Data
Jul. 5, 2024 (KR) 10-2024-0089117

(51) Int. Cl. H10F 39/00; G02B 3/00; G02B 5/20; H10F 39/18

(52) U.S. Cl. CPC H10F 39/8063; G02B 3/0043; G02B 5/208; H10F 39/182

(57) ABSTRACT

An optical filter device includes a meta-lens layer including a plurality of nanostructures, and an infrared filter configured to block light belonging to an infrared wavelength range among light passing through the meta-lens layer. The meta-lens layer includes a plurality of meta-regions distinguished according to distance from a center of the meta-lens layer, the plurality of meta-regions include unit groups corresponding to the plurality of meta-regions, respectively, and each of the unit groups includes at least two nanostructures. As the distance from the center of the meta-lens layer to each of the plurality of meta-regions increases, a difference in cross-sectional areas between a largest nanostructure and a smallest nanostructure in the unit group corresponding to the meta-region increases.

### CROSS-REFERENCE TO RELATED APPLICATION

This application is based on and claims priority under 35 U.S.C. § 119 to Korean Patent Application No. 10-2024-0089117, filed on Jul. 5, 2024, in the Korean Intellectual Property Office, the disclosure of which is incorporated by reference herein in its entirety.

### BACKGROUND

Aspects of the inventive concept relate to an optical filter device and an image sensor including the optical filter device, and more particularly, to an optical filter device in which nanostructures are arranged such that the difference in cross-sectional areas of nanostructures in a unit group changes according to the distance from the center of a meta-lens layer.

Image sensors capture 2-dimensional or 3-dimensional images of objects. An image sensor creates an image of an object by using a photoelectric conversion element that reacts to the intensity of light reflected from the object. Image sensors may be provided in electronic devices, such as digital cameras, camcorders, and mobile phones.

In an image sensor, an optical filter device may be required to reduce optical distortion caused by light outside the visible light range or to improve visibility affected by light outside the visible light range. When an infrared filter is disposed in an upper portion of an image sensor to reduce the size of an electronic device, that is, in an on-chip infrared filter, the transmission characteristics may vary depending on the angle of incidence of light incident onto the infrared filter, and the difference in sensitivities thereof may occur depending on the angle of incidence.

Accordingly, technology is required to reduce the difference in transmission characteristics according to the angle of incidence of light incident onto an infrared filter.

### SUMMARY

Aspects of the inventive concept provide an optical filter device in which a meta-lens layer includes a plurality of nanostructures, wherein, as a distance from the center of the meta-lens layer increases, the difference in the cross-sectional areas of nanostructures in a unit group corresponding to the distance increases. Accordingly, the difference in spectral characteristics according to the angle of incidence of light is reduced.

According to an aspect of the inventive concept, there is provided an optical filter device including a meta-lens layer including a plurality of nanostructures, and an infrared filter configured to block light belonging to an infrared wavelength range among light passing through the meta-lens layer, wherein the meta-lens layer includes a plurality of meta-regions distinguished according to distance from a center of the meta-lens layer, the plurality of meta-regions include unit groups corresponding to the plurality of meta-regions, respectively, and each of the unit groups includes at least two nanostructures, and wherein, as the distance from the center of the meta-lens layer to each of the plurality of meta-regions increases, a difference in cross-sectional areas between a largest nanostructure having a largest cross-sectional area and a smallest nanostructure having a smallest cross-sectional area, among the at least two nanostructures in the unit group corresponding to the meta-region, increases.

According to another aspect of the inventive concept, there is provided an image sensor including a pixel array in which a plurality of pixels are arranged, a color filter disposed on the pixel array, a light-collecting lens layer disposed on the color filter and configured to focus light onto the pixel array, an infrared filter disposed on the light-collecting lens layer and configured to block light in an infrared wavelength range, and a meta-lens layer including a plurality of nanostructures, wherein the meta-lens layer includes unit groups corresponding to distances from a center of the meta-lens layer, and each of the unit groups includes a plurality of nanostructures, and wherein, as a distance from the center of the meta-lens layer increases, a difference in cross-sectional areas of the nanostructures in the unit groups corresponding to distances from the center of the meta-lens layer increases.

According to another aspect of the inventive concept, there is provided an optical filter device including a meta-lens layer including a first meta-region and a second meta-region, and an infrared filter configured to block light belonging to an infrared wavelength range among light passing through the meta-lens layer, wherein a distance from a center of the meta-lens layer to the second meta-region is greater than a distance from the center of the meta-lens layer to the first meta-region, the first meta-region includes a first unit group, including a plurality of nanostructures, repeatedly arranged in the first meta-region, the second meta-region includes a second unit group, including a plurality of nanostructures, repeatedly arranged in the second meta-region, and a difference in diameters of a plurality of nanostructures in the second unit group is greater than a difference in diameters of a plurality of nanostructures in the first unit group.

### BRIEF DESCRIPTION OF THE DRAWINGS

Embodiments will be more clearly understood from the following detailed description taken in conjunction with the accompanying drawings in which:

FIG. 1 is a block diagram showing an optical filter device according to an embodiment;

FIG. 2 is a diagram illustrating a meta-lens layer according to an embodiment;

FIG. 3 is a diagram illustrating the arrangement of unit groups according to an embodiment;

FIG. 4A is a diagram illustrating unit groups according to an embodiment;

FIG. 4B is a diagram illustrating the cross-sectional areas of nanostructures according to an embodiment;

FIG. 5A is a diagram illustrating a central region of meta-regions according to an embodiment;

FIG. 5B is a cross-sectional view of a unit group of FIG. 5A taken along line I-I′;

FIG. 6 is a diagram illustrating nanostructures according to an embodiment;

FIG. 7A is a diagram illustrating the arrangement of nanostructures according to an embodiment;

FIG. 7B is a cross-sectional view of a unit group of FIG. 7A taken along line I-I′;

FIG. 8 is a diagram illustrating the arrangement of nanostructures according to an embodiment;

FIG. 9A is a diagram showing an example in which nanostructures according to an embodiment are gradually arranged according to the sizes of cross-sectional areas thereof;

FIG. 9B is a cross-sectional view of a unit group of FIG. 9A taken along line I-I′;

FIG. 10 is a diagram showing an example in which different numbers of nanostructures according to an embodiment are arranged in unit groups;

FIG. 11 is a diagram illustrating a meta-lens layer including a plurality of layers, according to an embodiment;

FIG. 12 is a diagram illustrating an infrared filter according to an embodiment;

FIG. 13 is a diagram illustrating an image sensor including an optical filter device according to an embodiment;

FIG. 14 is a cross-sectional view of an image sensor according to an embodiment;

FIG. 15 is a cross-sectional view of an image sensor according to an embodiment; and

FIG. 16 is a block diagram showing an electronic device according to an embodiment.

### DETAILED DESCRIPTION OF THE EMBODIMENTS

Hereinafter, embodiments are described in detail with reference to the accompanying drawings. The same reference numerals are given to the same elements in the drawings, and repeated descriptions thereof are omitted. The size of each component shown in the drawings may be exaggerated for clarity and convenience of description.

Hereinafter, when an element is referred to as being “above” or “on” another element, not only may the element be directly above and in contact with another element, but also the element may be above but not in contact with another element. When an element is referred to as being “directly connected” or “directly coupled” to another element, or as “contacting,” “in contact with,” or “contact” another element, there are no intervening elements present at the point of contact.

Although terms, such as ‘first’ and ‘second’, may be used to describe various elements, these terms are only used to distinguish one component from other components. These terms are not intended to limit the difference in materials or structures of elements.

The singular forms include the plural forms as well, unless the context clearly indicates otherwise. In addition, when it is described that a part “includes” a certain component, this indicates that the part may further include other components, rather than excluding other components, unless specifically stated to the contrary.

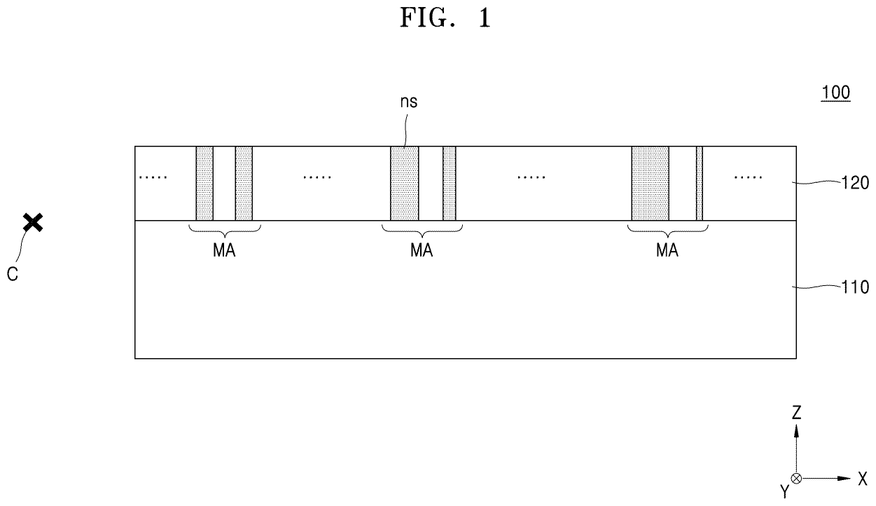

FIG. 1 is a block diagram showing an optical filter device 100 according to an embodiment.

Referring to FIG. 1, the optical filter device 100 may include an infrared filter 110 and a meta-lens layer 120. The optical filter device 100 may extend in a first direction (X direction) and a second direction (Y direction) perpendicular to the first direction (X direction). The infrared filter 110 may allow light having some wavelengths among the light passing through the meta-lens layer 120 to pass therethrough. In an embodiment, the infrared filter 110 may include an infrared cut filter that transmits visible light and blocks infrared light. For example, the infrared filter 110 may block light in at least a portion of a wavelength range of about 750 nm to about 1 mm. For example, the infrared filter 110 may block light in a range of about 750 nm to about 3,000 nm, that is, in the near-infrared wavelength range. However, the embodiment is not necessarily limited thereto, and the infrared filter 110 may block a wide range of light within the infrared wavelength range.

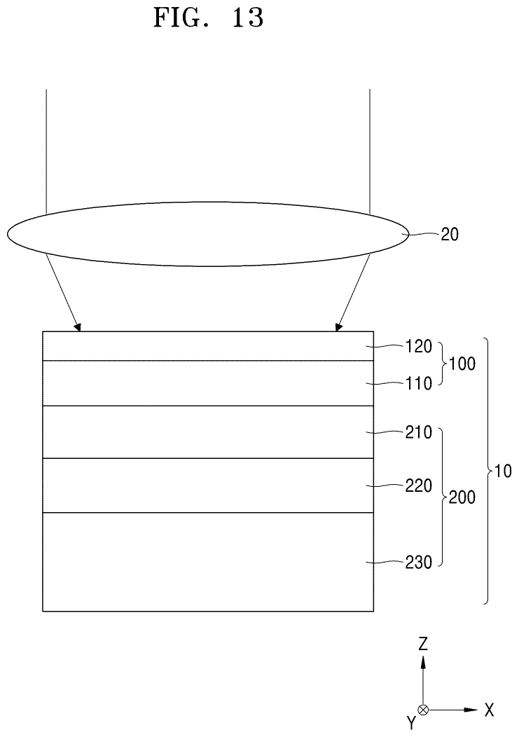

When light passing through a lens assembly (e.g., a lens assembly 20 of FIG. 13) that focuses light is directly incident onto the infrared filter 110, the transmission characteristics of light passing through the infrared filter 110 may vary depending on the angle of incidence of the light. For example, as the angle of incidence increases, the transmission wavelength of the infrared filter 110 may become shorter and the transmittance may decrease. The light having transmission characteristics that vary depending on the angle of incidence of light may reach a pixel array (e.g., a pixel array 230 of FIG. 13) of an image sensor (e.g., an image sensor 10 of FIG. 13), and thus, the spectrum of the image sensor may vary. Therefore, it is necessary to reduce the difference in transmission characteristics according to the angles of incidence of light when the light passes through the infrared filter 110. It is necessary to reduce the difference between the transmission angle of light passing through the center of the infrared filter 110 and the transmission angle of light passing through the edge of the infrared filter 110. The optical filter device 100 according to an embodiment has a meta-lens layer 120, and thus, the difference in transmission characteristics according to the angles of incidence of light when the light passes through the infrared filter 110 may be reduced.

The optical filter device 100 may include the meta-lens layer 120. The meta-lens layer 120 may include a plurality of nanostructures ns. The light passing through a lens assembly may reach the meta-lens layer 120. At least a portion of the light passing through the meta-lens layer 120 may pass through the infrared filter 110. The flow of incident light may be controlled based on the nanostructures ns arranged in the meta-lens layer 120. The nanostructures ns may be arranged to mitigate differences in the transmission characteristics of light passing through the infrared filter 110 depending on the angle of incidence. In an embodiment, a region other than the nanostructures ns in the meta-lens layer 120 may include a material having a lower refractive index than the nanostructures ns. For example, the region other than the nanostructures ns in the meta-lens layer 120 may include SiO₂, air, siloxane-based spin on glass (SOG), etc. However, the embodiment is not necessarily limited thereto.

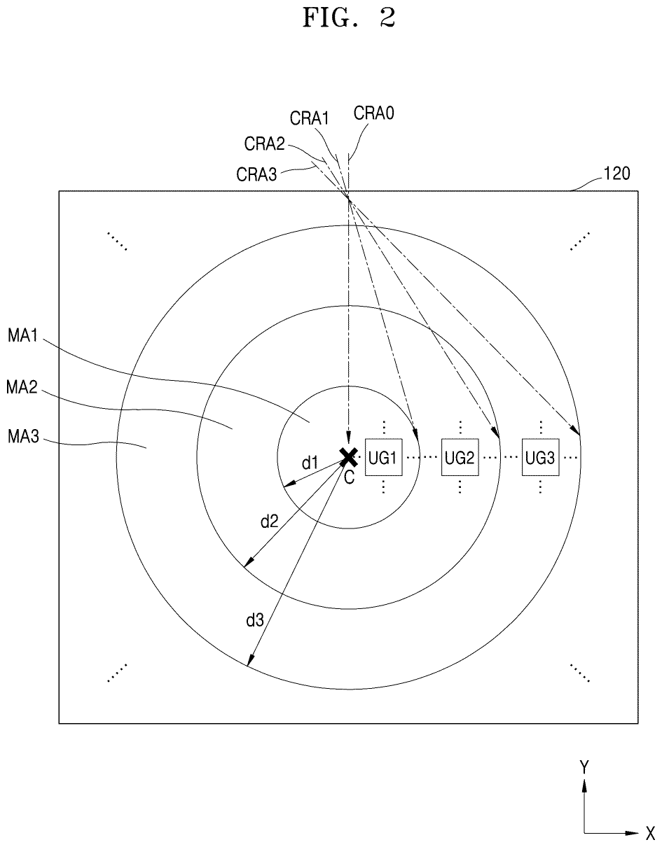

The meta-lens layer 120 may include a plurality of meta-regions MA, and each of the meta-regions MA may include the nanostructures ns. The meta-regions MA may be distinguished according to the distance from a center c of the meta-lens layer 120. Each meta-region MA may include at least two nanostructures ns. The nanostructure ns may have a relatively higher refractive index than surrounding materials. For example, the nanostructure ns may include, but is not necessarily limited to, at least one of c-Si, p-Si, a-Si, and group III-V compound semiconductors (GaAs, GaP, GaN, GaAs, etc.), SiC, TiO₂, and SiN. Also, FIG. 1 illustrates that two nanostructures ns are arranged in each of the meta-regions MA, but this is for convenience of description. The number of nanostructures ns in the meta-region MA is not necessarily limited thereto. The meta-region MA is described in detail below with reference to FIG. 2.

The difference in cross-sectional areas of the nanostructure ns in the meta-region MA may vary depending on the distance from the center c of the meta-lens layer 120. The light may be refracted due to the difference in cross-sectional areas of the nanostructures ns in the meta-region MA. Due to the differences in cross-sectional areas of the nanostructures ns in the meta-regions MA, light incident on the meta-regions MA may be refracted differently.

In an embodiment, as a distance from the center c of the meta-lens layer 120 increases, the difference in cross-sectional areas of the nanostructures ns in the meta-region MA corresponding to the distance therefrom may increase. The difference in cross-sectional areas of nanostructures ns may refract light. As the difference in cross-sectional areas of nanostructures ns increases, light may be refracted more.

For example, regarding the first meta-region that is relatively close to the center c in an X direction, the difference in cross-sectional areas of the nanostructures ns in the first meta-region may be relatively small, and the nanostructures ns in the first meta-region may form a relatively small refractive index. The transmission angle of light passing through the infrared filter 110 close to the center c in the X direction may have a small difference from the angle of incidence of the light. The light incident on the first meta-region that is relatively close to the center c in the X direction may be relatively less refracted through the nanostructures ns in the first meta-region and may then pass through the infrared filter 110.

For example, regarding the second meta-region that is relatively far from the center c in the X direction in FIG. 1, the difference in cross-sectional areas of the nanostructures ns in the second meta-region may be relatively large, and the nanostructures ns in the second meta-region may form a relatively large refractive index. The transmission angle of light passing through the infrared filter 110 that is far from the center c in the X direction may be different from the transmission angle of light passing through the infrared filter 110 that is close to the center c in the X direction. In order to reduce the difference in transmission characteristics depending on the angle of incidence of light when the light passes through the infrared filter 110, it is necessary to reduce the difference in transmission angles between the light passing through the infrared filter 110 close to the center c and the light passing through the infrared filter 110 far from the center c. Light may be refracted through the nanostructures ns in the second meta-region, and the refracted light may pass through the infrared filter 110. Accordingly, the light may have a similar transmission angle to the light passing through the infrared filter 110 that is close to the center c in the X direction. As the distance from the center c increases, the difference between the transmission angle of light passing through the infrared filter 110 far from the center c and the transmission angle of light passing through the infrared filter 110 close to the center c may increase. Accordingly, as a distance from the center c of the meta-lens layer 120 increases, the difference in cross-sectional areas of the nanostructures ns in the meta-region MA corresponding to the distance therefrom may increase.

In an embodiment, the meta-lens layer 120 may be disposed on the infrared filter 110. The meta-lens layer 120 may be disposed above the infrared filter 110 in a third direction (Z direction), which is perpendicular to the first direction (X direction) and the second direction (Y direction). However, the embodiment is not necessarily limited thereto, and the meta-lens layer 120 may be disposed below the infrared filter 110. FIG. 1 illustrates that the meta-lens layer 120 is disposed directly on the infrared filter 110, but the embodiment is not necessarily limited thereto. The infrared filter 110 and the meta-lens layer 120 may be spaced apart from each other, and a spacer layer for supporting the meta-lens layer 120 may be located between the infrared filter 110 and the meta-lens layer 120.

In an embodiment, the meta-lens layer 120 and the infrared filter 110 may be formed on a single substrate. The infrared filter 110 and the meta-lens layer 120 may be sequentially formed on the substrate. However, the embodiment is not necessarily limited thereto, and the meta-lens layer 120 and the infrared filter 110 may be sequentially formed on the substrate.

The nanostructures ns are arranged such that, as the distance from the center c of the meta-lens layer 120 increases, the difference in cross-sectional areas of the nanostructures ns in a unit group corresponding to the distance therefrom increases. Accordingly, the light may be refracted according to the angle of incidence, and the difference in transmission angles of light transmitted through the infrared filter 110 according to the angle of incidence may be mitigated. As a result, the difference in spectral characteristics according to the angle of incidence of light may be reduced. Accordingly, the difference in sensitivities of pixels according to the angle of incidence may be reduced, and the difference in signals across the entire region of a pixel array may be reduced.

FIG. 2 is a diagram illustrating a meta-lens layer 120 according to an embodiment. Repeated descriptions as those given above are omitted. FIG. 2 illustrates that the meta-lens layer 120 includes three meta-regions MA, such as a first meta-region MA1, a second meta-region MA2, and a third meta-region MA3, but the embodiment is not necessarily limited thereto. The meta-lens layer 120 may include two or more meta-regions MA.

Referring to FIG. 2, the meta-lens layer 120 may include a plurality of meta-regions MA. The meta-regions MA may be distinguished according to the distance from a center c of the meta-lens layer 120. For example, the first meta-region MA1 may be relatively close to the center C. For example, the first meta-region MA1 may include a region of the meta-lens layer 120 which is located within a first distance d1 from the center C. The second meta-region MA2 may be relatively far from the center C. The distance from the center C to the second meta-region MA2 may be greater than the distance from the center C to the first meta-region MA1. For example, the second meta-region MA2 may include a region of the meta-lens layer 120 which is located between the first distance d1 and a second distance d2 from the center C. The third meta-region MA3 may be relatively further away from the center C. The distance from the center C to the third meta-region MA3 may be greater than the distance from the center C to the second meta-region MA2. For example, the third meta-region MA3 may include a region of the meta-lens layer 120 which is located between the second distance d2 and a third distance d3 from the center C.

In an embodiment, the plurality of meta-regions MA may be distinguished based on a chief ray angle (CRA) value. The CRA value may represent the angle of incident light that is incident on the center C of the meta-lens layer 120. The CRA value may vary across the meta-lens layer 120. The CRA value of the meta-lens layer 120 may increase with the distance from the center C.

The angle of incidence of incident light, which is incident on the center C of the meta-lens layer 120, may have a center CRA value CRA0. The angle of incidence of incident light, which is incident on the first meta-region MA1, may have a first CRA value CRA1. The center CRA value CRA0 to the first CRA value CRA1 may correspond to the first meta-region MA1. For example, the first meta-region MA1 may include regions of the meta-lens layer 120 having CRA values CRA0 up to the first CRA value CRA1. The angle of incidence of incident light, which is incident on the second meta-region MA2, may have a second CRA value CRA2. The second CRA value CRA2 may correspond to the second meta-region MA2. For example, the second meta-region MA2 may include regions of the meta-lens layer 120 having CRA values greater than the first CRA value CRA1 and less than or equal to the second CRA value CRA2. The angle of incidence of incident light, which is incident on the third meta-region MA3, may have a third CRA value CRA3. The third CRA value CRA3 may correspond to the third meta-region MA3. For example, the third meta-region MA3 may include regions of the meta-lens layer 120 having CRA values greater than the second CRA value CRA2 and less than or equal to the third CRA value CRA3. For example, the center CRA value CRA0 may be 0°, and a relationship, such as CRA0<CRA1<CRA2<CRA3, may be established.

The plurality of meta-regions MA may include unit groups UG respectively corresponding to the plurality of meta-regions MA. The unit groups UG may each include at least two nanostructures (e.g., nanostructures ns of FIG. 1). The unit group UG corresponding to each of the plurality of meta-regions MA may be repeatedly arranged within the corresponding meta-region MA.

For example, a first meta-region MA1 may include a first unit group UG1. The first unit group UG1 may be repeatedly arranged in the first meta-region MA1. The second meta-region MA2 may include a second unit group UG2, and the second unit group UG2 may be repeatedly arranged in the second meta-region MA2. The third meta-region MA3 may include a third unit group UG3, and the third unit group UG3 may be repeatedly arranged in the third meta-region MA3.

Each of the unit groups UG may include at least two nanostructures (e.g., the nanostructures ns of FIG. 1), and the difference in cross-sectional areas of the nanostructures ns in unit groups UG may vary. The difference in cross-sectional areas of the nanostructures ns in the unit groups UG respectively corresponding to the meta-regions MA may vary. As the distance from the center C to the meta-region MA increases, the difference in cross-sectional areas of the nanostructures ns in the unit group UG corresponding to the meta-region MA may increase. For example, the difference in cross-sectional areas of the nanostructures ns in the second unit group UG2 may be greater than the difference in cross-sectional areas of the nanostructures ns in the first unit group UG1.

In an embodiment, as the distance from the center C to the meta-region MA increases, a difference in cross-sectional areas between a largest nanostructure having a largest cross-sectional area and a smallest nanostructure having a smallest cross-sectional area among the nanostructures ns in the unit group UG corresponding to the meta-region MA may increase. For example, the difference in cross-sectional areas between the largest nanostructure and the smallest nanostructure among the nanostructures ns in the second unit group UG2 may be greater than the difference in cross-sectional areas between the largest nanostructure and the smallest nanostructure among the nanostructures ns in the first unit group UG1. The difference in cross-sectional areas between the largest nanostructure and the smallest nanostructure among the nanostructures ns in the third unit group UG3 may be greater than the difference in cross-sectional areas between the largest nanostructure and the smallest nanostructure among the nanostructures ns in the second unit group UG2.

In an embodiment, the nanostructures ns in the unit group UG may each have a cylindrical shape. Since the nanostructure ns has a cylindrical shape, the cross-sectional area of the nanostructure ns may be determined on the basis of the diameter of the nanostructure ns. As the distance from the center C to the meta-region MA increases, the difference in diameters of the nanostructures ns in the unit group UG corresponding to the meta-region MA may increase. For example, the difference in diameters of the nanostructures ns in the second unit group UG2 may be greater than the difference in diameters of the nanostructures ns in the first unit group UG1.

In an embodiment, as the distance from the center C to the meta-region MA increases, a difference in diameters between a nanostructure having a largest diameter and a nanostructure having a smallest diameter among the nanostructures ns in the unit group UG corresponding to the meta-region MA may increase. For example, the difference in diameters between the nanostructure having the largest diameter and the nanostructure having the smallest diameter among the nanostructures ns in the second unit group UG2 may be greater than the difference in diameters between the nanostructure having the largest diameter and the nanostructure having the smallest diameter among the nanostructures ns in the first unit group UG1.

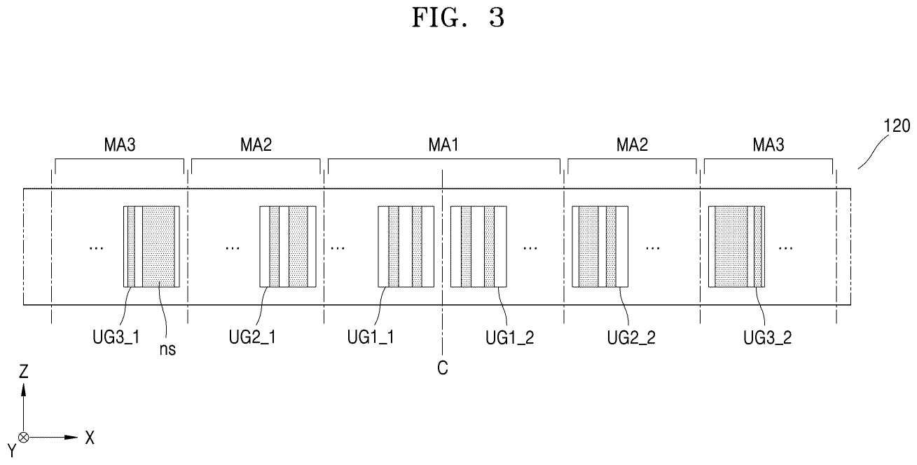

FIG. 3 is a diagram illustrating the arrangement of unit groups according to an embodiment. FIG. 3 shows a portion of the meta-lens layer 120 of FIG. 2.

Referring to FIG. 3, the plurality of meta-regions MA may include unit groups UG respectively corresponding to the plurality of meta-regions MA. The unit group UG may include at least two nanostructures ns. FIG. 3 illustrates that each of the unit groups UG includes two nanostructures ns, but this is only an example. The embodiment is not necessarily limited thereto. The unit group UG corresponding to each of the plurality of meta-regions MA may be repeatedly arranged within the corresponding meta-region MA.

With respect to the center C of the meta-lens layer 120, the nanostructures ns in each of the unit groups UG may form a symmetrical structure. For example, the first meta-region MA1 may include a first unit group UG1 (or referred to as first unit group UG1_1 or UG1_2) that is repeatedly arranged. The nanostructure ns in the first unit group UG1_1 may be identical to the nanostructure ns in the first unit group UG1_2. The first unit group UG1_1 and the first unit group UG1_2 may be symmetrical to each other with respect to the center C. The second meta-region MA2 may include a second unit group UG2 (or referred to as second unit group UG2_1 or UG2_2) that is repeatedly arranged. The nanostructure ns in the second unit group UG2_1 may be identical to the nanostructure ns in the second unit group UG2_2. The second unit group UG2_1 and the second unit group UG2_2 may be symmetrical to each other with respect to the center C. The third meta-region MA3 may include a third unit group UG3 (or referred to as third unit group UG3_1 or UG3_2) that is repeatedly arranged. The nanostructure ns in the third unit group UG3_1 may be identical to the nanostructure ns in the third unit group UG3_2. The third unit group UG3_1 and the third unit group UG3_2 may be symmetrical to each other with respect to the center C.

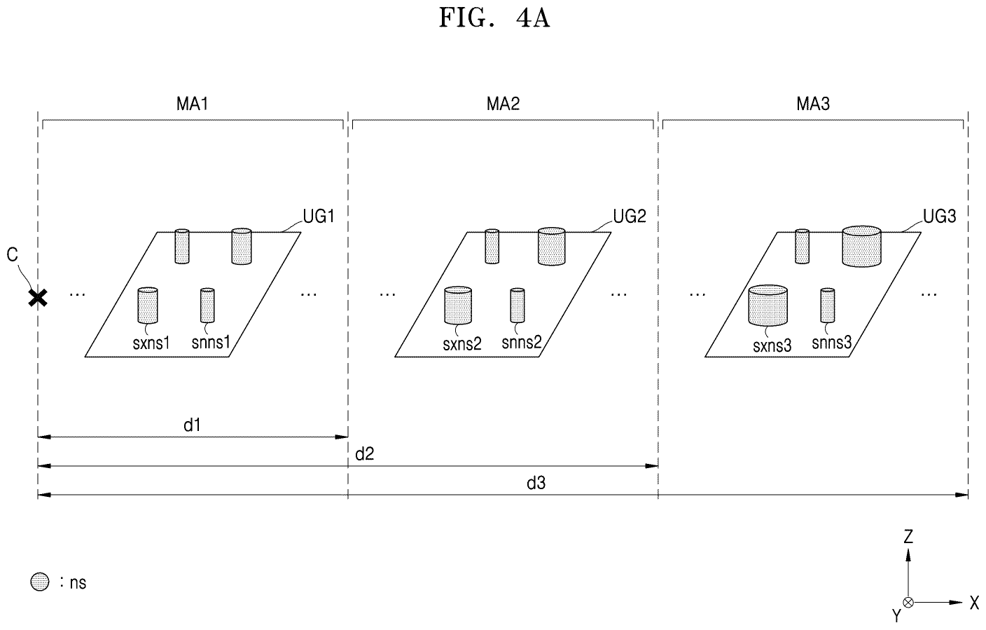

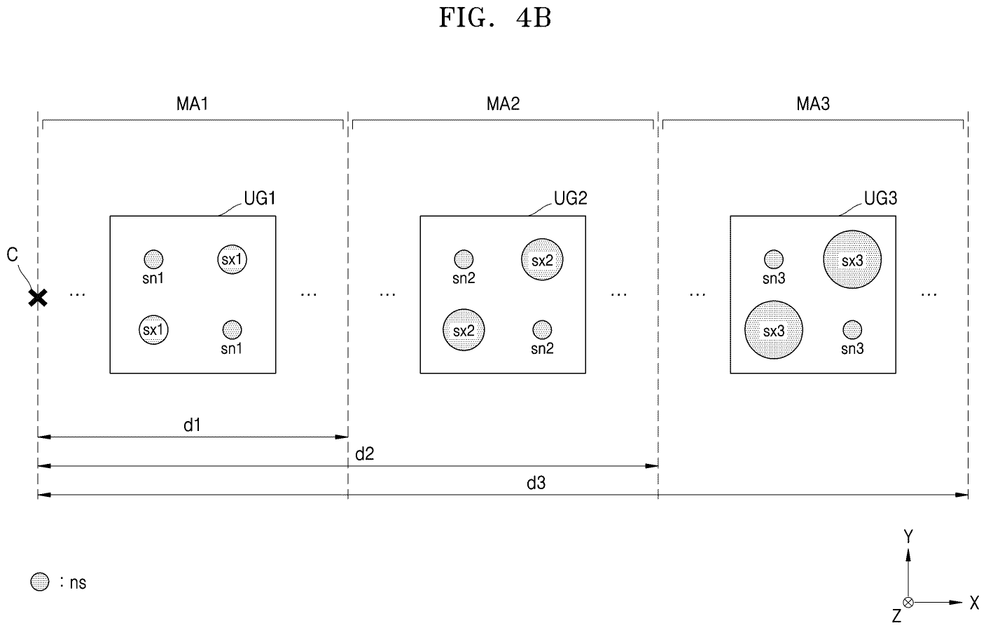

FIG. 4A is a diagram illustrating unit groups according to an embodiment. FIG. 4A illustrates the first meta-region MA1, the second meta-region MA2, and the third meta-region MA3, which are described above with reference to FIG. 2. The first meta-region MA1 may be relatively close to the center C, the second meta-region MA2 may be further from the center C than the first meta-region MA1, and the third meta-region MA3 may be further from the center C than the second meta-region MA2.

Referring to FIG. 4A, in each of the plurality of meta-regions MA, the unit group UG corresponding to each of the meta-regions MA may be repeatedly arranged. A single unit group UG may include at least two nanostructures ns. Although FIG. 4A illustrates that the single unit group UG includes four nanostructures ns, the embodiment is not necessarily limited thereto. The single unit group UG may include various numbers of nanostructures ns. Also, the unit groups UG respectively corresponding to the meta-regions MA may include different numbers of nanostructures ns.

In the first meta-region MA1, the first unit group UG1 may be repeatedly arranged. The first meta-region MA1 may include four nanostructures ns. In the second meta-region MA2, the second unit group UG2 may be repeatedly arranged. The second meta-region MA2 may include four nanostructures ns. In the third meta-region MA3, the third unit group UG3 may be repeatedly arranged. The third meta-region MA3 may include four nanostructures ns. However, the embodiment is not necessarily limited thereto, and the first meta-region MA1, the second meta-region MA2, and the third meta-region MA3 may include various numbers of nanostructures ns.

The difference in cross-sectional areas of the nanostructures ns in the unit groups UG may vary. The difference in cross-sectional areas of the nanostructures ns in the unit groups UG respectively corresponding to the meta-regions MA may vary. As the distance from the center C to the meta-region MA increases, the difference in cross-sectional areas of the nanostructures ns in the unit group UG corresponding to the meta-region MA may increase. The difference in cross-sectional areas of nanostructures provided in the unit group UG and having different sizes may increase as the distance from the center C to the meta-region MA increases. For example, the difference in cross-sectional areas of the nanostructures ns in the second unit group UG2 may be greater than the difference in cross-sectional areas of the nanostructures ns in the first unit group UG1. The difference in cross-sectional areas of the nanostructures ns in the third unit group UG3 may be greater than the difference in cross-sectional areas of the nanostructures ns in the second unit group UG2.

The unit group UG may include a plurality of nanostructures ns, and the plurality of nanostructures ns may include a largest nanostructure sxns (i.e., a nanostructure sxns having a first cross-sectional area) and a smallest nanostructure snns (i.e., a second nanostructure snns having a second cross-sectional area). The largest nanostructure sxns may represent the nanostructure ns having the largest cross-sectional area among the nanostructures ns in a certain unit group UG. The smallest nanostructure snns may represent the nanostructure ns having the smallest cross-sectional area among the nanostructures ns in a certain unit group UG. The cross-sectional area of the nanostructure ns may represent the area or size of the cross-section of the nanostructure ns taken in the X direction. The cross-sectional area of the nanostructure ns may represent the cross-sectional area in a region in which the nanostructure ns is adjacent to the meta-region MA. In an embodiment, the nanostructure ns may have a cylindrical shape. However, the embodiment is not necessarily limited thereto.

The first unit group UG1 may include a first largest nanostructure sxns1 and a first smallest nanostructure snns1. The first largest nanostructure sxns1 may represent the nanostructure ns having the largest cross-sectional area among the nanostructures ns in the first unit group UG1, and the first smallest nanostructure snns1 may represent the nanostructure ns having the smallest cross-sectional area among the nanostructures ns in the first unit group UG1. The second unit group UG2 may include a second largest nanostructure sxns2 and a second smallest nanostructure snns2. The second largest nanostructure sxns2 may represent the nanostructure ns having the largest cross-sectional area among the nanostructures ns in the second unit group UG2, and the second smallest nanostructure snns2 may represent the nanostructure ns having the smallest cross-sectional area among the nanostructures ns in the second unit group UG2. The third unit group UG3 may include a third largest nanostructure sxns3 and a third smallest nanostructure snns3. The third largest nanostructure sxns3 may represent the nanostructure ns having the largest cross-sectional area among the nanostructures ns in the third unit group UG3, and the third smallest nanostructure snns3 may represent the nanostructure ns having the smallest cross-sectional area among the nanostructures ns in the third unit group UG3.

In an embodiment, as the distance from the center C to the meta-region MA increases, a difference in cross-sectional areas between the largest nanostructure sxns and the smallest nanostructure snns among the nanostructures ns in the unit group UG corresponding to the meta-region MA may increase. The first unit group UG1 may correspond to the first meta-region MA1, the second unit group UG2 may correspond to the second meta-region MA2, and the third unit group UG3 may correspond to the third meta-region MA3. For example, the difference in cross-sectional areas between the second largest nanostructure sxns2 and the second smallest nanostructure snns2 in the second unit group UG2 may be greater than the difference in cross-sectional areas between the first largest nanostructure sxns1 and the first smallest nanostructure snns1 in the first unit group UG1. For example, the difference in cross-sectional areas between the third largest nanostructure sxns3 and the third smallest nanostructure snns3 in the third unit group UG3 may be greater than the difference in cross-sectional areas between the second largest nanostructure sxns2 and the second smallest nanostructure snns2 in the second unit group UG2.

FIG. 4B is a diagram illustrating the cross-sectional areas of nanostructures according to an embodiment. FIG. 4B shows the cross-sectional area of the nanostructure ns of FIG. 4A. Repeated descriptions as those given above are omitted.

Referring to FIGS. 4A and 4B, the first unit group UG1 may include a first largest nanostructure sxns1 and a first smallest nanostructure snns1. The cross-sectional area of the first largest nanostructure sxns1 may be a first largest cross-sectional area sx1, and the cross-sectional area of the first smallest nanostructure snns1 may be a first smallest cross-sectional area sn1. The second unit group UG2 may include a second largest nanostructure sxns2 and a second smallest nanostructure snns2. The cross-sectional area of the second largest nanostructure sxns2 may be a second largest cross-sectional area sx2, and the cross-sectional area of the second smallest nanostructure snns2 may be a second smallest cross-sectional area sn2. The third unit group UG3 may include a third largest nanostructure sxns3 and a third smallest nanostructure snns3. The cross-sectional area of the third largest nanostructure sxns3 may be a third largest cross-sectional area sx3, and the cross-sectional area of the third smallest nanostructure snns3 may be a third smallest cross-sectional area sn3.

As the distance from the center C to the meta-region MA increases, a difference in cross-sectional areas between the largest nanostructure sxns and the smallest nanostructure snns among the nanostructures ns in the unit group UG corresponding to the meta-region MA may increase. For example, the difference between the second largest cross-sectional area sx2 and the second smallest cross-sectional area sn2 may be greater than the difference between the first largest cross-sectional area sx1 and the first smallest cross-sectional area sn1. For example, the difference between the third largest cross-sectional area sx3 and the third smallest cross-sectional area sn3 may be greater than the difference between the second largest cross-sectional area sx2 and the second smallest cross-sectional area sn2.

In an embodiment, as the distance from the center C to each of the plurality of meta-regions MA increases, the cross-sectional area of the largest nanostructure sxns in the unit group UG corresponding to the meta-region MA may increase. For example, the second largest cross-sectional area sx2 may be greater than the first largest cross-sectional area sx1, and the third largest cross-sectional area sx3 may be greater than the second largest cross-sectional area sx2.

The cross-sectional areas of the smallest nanostructures snns in the unit groups UG may be the same. For example, the first smallest cross-sectional area sn1, the second smallest cross-sectional area sn2, and the third smallest cross-sectional area sn3 may have the same size. However, the embodiment is not necessarily limited thereto, and at least two or more cross-sectional areas of the smallest nanostructures snns in each of the unit groups UG may be different. For example, the first smallest cross-sectional area sn1, the second smallest cross-sectional area sn2, and the third smallest cross-sectional area sn3 may have different sizes.

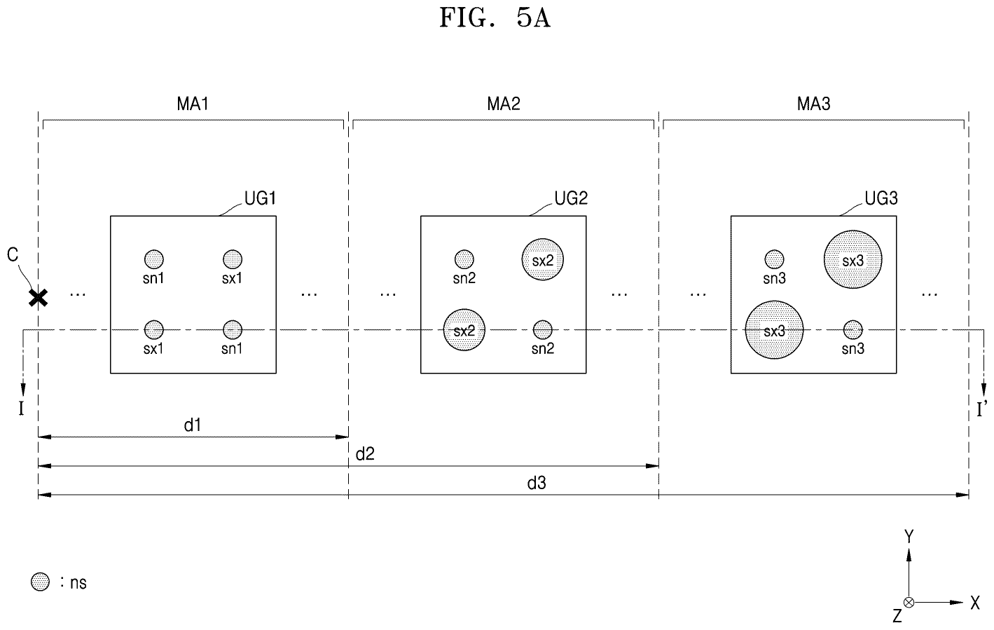

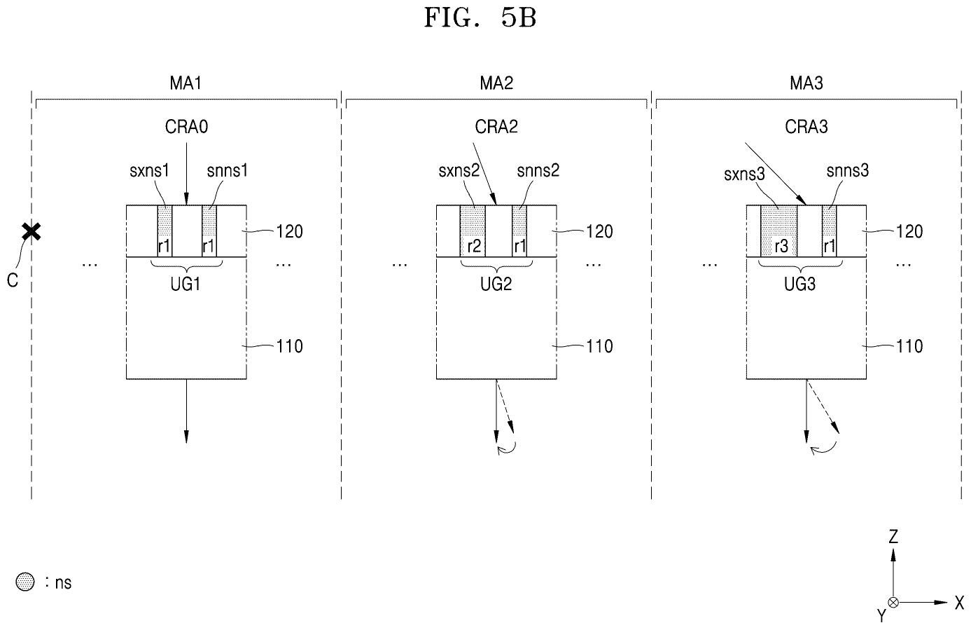

FIG. 5A is a diagram illustrating a central region of meta-regions according to an embodiment. Compared to FIG. 4B, a first unit group UG1 of FIG. 5A may include identical nanostructures ns. Repeated descriptions as those given above are omitted.

Referring to FIG. 5A, a meta-lens layer (e.g., the meta-lens layer 120 of FIG. 2) may include a first meta-region MA1, a second meta-region MA2, and a third meta-region MA3. In an embodiment, the first meta-region MA1 may include a center C of the meta-lens layer 120 and may be referred to as a central region. A first unit group UG1 may correspond to the central region, and the first unit group UG1 may be repeatedly arranged in the first meta-region MA1.

In an embodiment, nanostructures ns in the unit group corresponding to the central region may have the same cross-sectional area. For example, the first unit group UG1 may include the nanostructures ns having the same cross-sectional area. For example, the first unit group UG1 may include four nanostructures ns having the same cross-sectional area, but the number of nanostructures in the first unit group UG1 is not necessarily limited thereto.

A first smallest cross-sectional area sn1 and a first largest cross-sectional area sx1 may have the same size. For example, the difference between the first largest cross-sectional area sx1 and the first smallest cross-sectional area sn1 may be 0 and may be less than the difference between a second largest cross-sectional area sx2 and a second smallest cross-sectional area sn2. The difference between the second largest cross-sectional area sx2 and the second smallest cross-sectional area sn2 may be less than the difference between a third largest cross-sectional area sx3 and a third smallest cross-sectional area sn3. Hereinafter, descriptions are made assuming that all nanostructures ns in the first meta-region MA1 have the same cross-sectional area.

FIG. 5B is a cross-sectional view of the unit group of FIG. 5A taken along line I-I′. Repeated descriptions as those given above are omitted.

Referring to FIG. 5B, a cross-sectional view is shown in which an infrared filter 110 is disposed below a meta-lens layer 120. The meta-lens layer 120 may include the first meta-region MA1, the second meta-region MA2, and the third meta-region MA3. The first unit group UG1 may be repeatedly arranged in the first meta-region MA1, the second unit group UG2 may be repeatedly arranged in the second meta-region MA2, and the third unit group UG3 may be repeatedly arranged in the third meta-region MA3.

In an embodiment, the nanostructures ns in the unit group UG may each have a cylindrical shape. Since the nanostructure ns has a cylindrical shape, the cross-sectional area of the nanostructure ns may be determined on the basis of the diameter of the nanostructure ns. For example, the nanostructure ns may have a diameter in a range of about 80 nm to about 250 nm. However, the embodiment is not necessarily limited thereto. In FIG. 5B, descriptions are made assuming that the nanostructure ns has a cylindrical shape.

As the distance from the center C to the meta-region MA increases, the difference in diameters of the nanostructures ns in the unit group UG corresponding to the meta-region MA may increase. For example, the difference in diameters of the nanostructures ns in the second unit group UG2 may be greater than the difference in diameters of the nanostructures ns in the first unit group UG1. The difference in cross-sectional areas of the nanostructures ns in the second unit group UG2 may be greater than the difference in cross-sectional areas of the nanostructures ns in the first unit group UG1. For example, the difference in diameters of the nanostructures ns in the third unit group UG3 may be greater than the difference in diameters of the nanostructures ns in the second unit group UG2. The difference in cross-sectional areas of the nanostructures ns in the third unit group UG3 may be greater than the difference in cross-sectional areas of the nanostructures ns in the second unit group UG2.

In an embodiment, as the distance from the center C to the meta-region MA increases, a difference in diameters between a nanostructure having a largest diameter and a nanostructure having a smallest diameter among the nanostructures ns in the unit group UG corresponding to the meta-region MA may increase. For example, the diameter of a first largest nanostructure sxns1 in the first unit group UG1 may be a first diameter r1, and the diameter of a first smallest nanostructure snns1 may be the first diameter r1. The first largest nanostructure sxns1 and the first smallest nanostructure snns1 may have the same diameter. The diameter of a second largest nanostructure sxns2 in the second unit group UG2 may be a second diameter r2, and the diameter of a second smallest nanostructure snns2 may be the first diameter r1. The second diameter r2 may be greater than the first diameter r1. The difference between the second diameter r2 and the first diameter r1 may be greater than the difference between the first diameter r1 and the first diameter r1. The difference between the diameter of the second largest nanostructure sxns2 and the diameter of the second smallest nanostructure snns2 may be greater than the difference between the diameter of the first largest nanostructure sxns1 and the diameter of the first smallest nanostructure snns1. The difference in cross-sectional areas between the second largest nanostructure sxns2 and the second smallest nanostructure snns2 may be greater than the difference in cross-sectional areas between the first largest nanostructure sxns1 and the first smallest nanostructure snns1.

For example, the diameter of a third largest nanostructure sxns3 in the third unit group UG3 may be a third diameter r3, and the diameter of a third smallest nanostructure snns3 may be the first diameter r1. The third diameter r3 may be greater than the second diameter r2. The difference between the third diameter r3 and the first diameter r1 may be greater than the difference between the second diameter r2 and the first diameter r1. The difference between the diameter of the third largest nanostructure sxns3 and the diameter of the third smallest nanostructure snns3 may be greater than the difference between the diameter of the second largest nanostructure sxns2 and the diameter of the second smallest nanostructure snns2. The difference in cross-sectional areas between the third largest nanostructure sxns3 and the third smallest nanostructure snns3 may be greater than the difference in cross-sectional areas between the second largest nanostructure sxns2 and the second smallest nanostructure snns2.

The difference in cross-sectional areas of the nanostructures ns in the unit group UG may cause the occurrence of phase delay. As the difference in cross-sectional areas of the nanostructures ns increases, the diffraction angle may increase and the refractive index may also increase. The transmission angle of light passing through the meta-lens layer 120 and the infrared filter 110 may be controlled by utilizing the difference in cross-sectional areas of the nanostructures ns in the meta-lens layer 120.

It is assumed that the light having a center CRA value CRA0 may be incident on the first meta-region MA1, the light having a second CRA value CRA2 may be incident on the second meta-region MA2, and the light having a third CRA value CRA3 may be incident on the third meta-region MA3. Since the nanostructures ns in the first unit group UG1 have no or relatively small differences in cross-sectional areas, the light incident on the first meta-region MA1 may be refracted relatively less via the meta-lens layer 120. The transmission angle of light passing through the first meta-region MA1 and the infrared filter 110 may be similar to the value of the center CRA CRA0.

Since the difference in cross-sectional areas between the nanostructures ns in the second unit group UG2 is greater than the difference in cross-sectional areas between the nanostructures ns in the first unit group UG1, the light incident on the second meta-region MA2 may be refracted relatively more via the meta-lens layer 120. The light incident on the second meta-region MA2 may be refracted more than the light incident on the first meta-region MA1. The light passing through the second meta-region MA2 is refracted significantly. Therefore, even if the value of second CRA CRA2 is greater than the value of center CRA CRA0, the transmission angle of light of the second CRA CRA2 passing through the second meta-region MA2 and the infrared filter 110 may be similar to the value of center CRA CRA0.

Since the difference in cross-sectional areas between the nanostructures ns in the third unit group UG3 is greater than the difference in cross-sectional areas between the nanostructures ns in the second unit group UG2, the light incident on the third meta-region MA3 may be refracted relatively more via the meta-lens layer 120. The light incident on the third meta-region MA3 may be refracted more than the light incident on the second meta-region MA2. The light passing through the third meta-region MA3 is refracted significantly. Therefore, even if the value of third CRA CRA3 is greater than the value of second CRA CRA2, the transmission angle of light of the third CRA CRA3 passing through the third meta-region MA3 and the infrared filter 110 may be similar to the value of center CRA CRA0.

The nanostructures ns are arranged such that, as the distance from the center C to the meta-region MA increases, the difference in diameters between the nanostructure having the largest diameter and the nanostructure having the smallest diameter among the nanostructures ns in the unit group UG corresponding to the meta-region MA increases. Accordingly, the difference in the transmission angles of light passing through the infrared filter 110 according to the angles of incidence may be reduced. Therefore, the difference in transmission characteristics according to the angles of incidence of light when the light passes through the infrared filter 110 may be reduced. Accordingly, the difference in sensitivities of pixels according to the angle of incidence may be reduced, and the difference in signals across the entire region of a pixel array may be reduced.

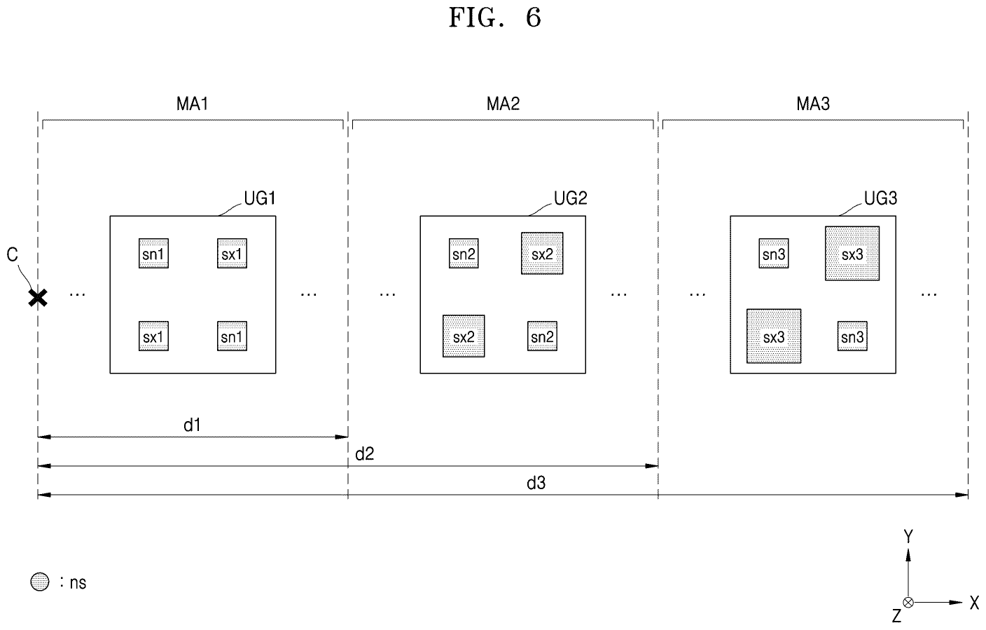

FIG. 6 is a diagram illustrating nanostructures according to an embodiment. Compared to FIG. 5A, the cross-section of each of nanostructures ns of FIG. 6 may have a quadrangular shape. Repeated descriptions as those given above are omitted.

Referring to FIG. 6, the cross-section of each of the nanostructures ns arranged in meta-regions MA may have a quadrangular shape. The cross-section of a region in which the nanostructures ns is in contact with the meta-region MA may have a quadrangular shape. In an embodiment, the nanostructures ns in the unit group UG may each have a quadrangular pillar shape. The cross-sectional area of the nanostructure ns may represent the area or size of the cross-section of the nanostructure ns having the quadrangular pillar taken in the X direction. Although FIG. 6 illustrates that all nanostructures ns have quadrangular pillar shapes, the embodiment is not necessarily limited thereto. The nanostructures ns having other shapes may be arranged in a mixed manner. For example, each of the unit groups UG may include quadrangular pillar-shaped nanostructures ns and cylindrical nanostructures ns.

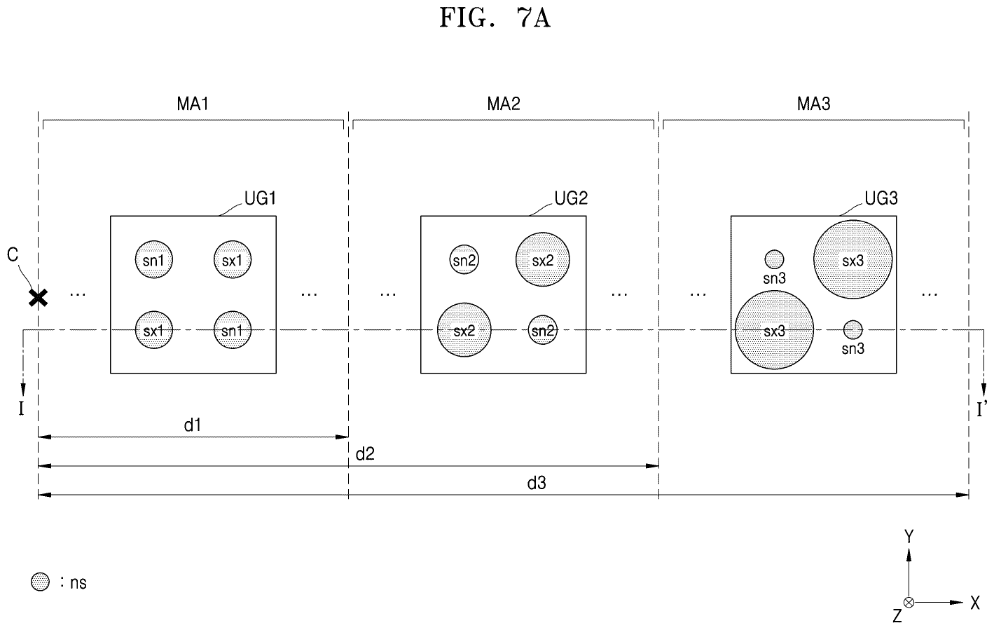

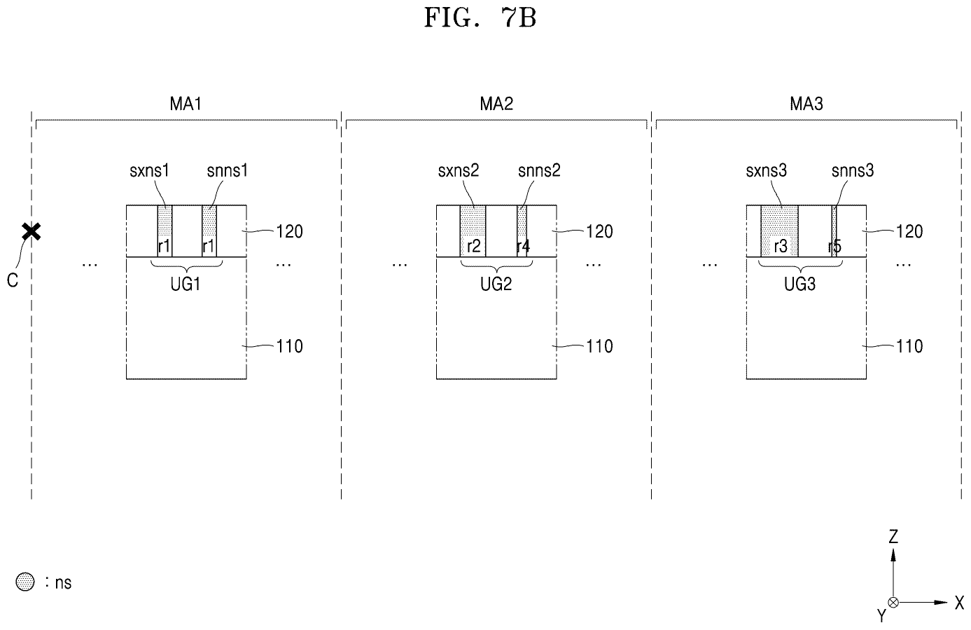

FIG. 7A is a diagram illustrating the arrangement of nanostructures according to an embodiment. Repeated descriptions as those given above are omitted.

Referring to FIG. 7A, as the distance from the center C to the meta-region MA increases, the difference in cross-sectional areas of the nanostructures ns in the unit group UG corresponding to the meta-region MA may increase. The difference between a first largest cross-sectional area sx1 and a first smallest cross-sectional area sn1 may be less than the difference between a second largest cross-sectional area sx2 and a second smallest cross-sectional area sn2. The difference between the second largest cross-sectional area sx2 and the second smallest cross-sectional area sn2 may be less than the difference between a third largest cross-sectional area sx3 and a third smallest cross-sectional area sn3.

In an embodiment, as the distance from the center C to each of the plurality of meta-regions MA increases, a cross-sectional area sx of the largest nanostructure in the unit group UG corresponding to the meta-region MA may increase. For example, the second largest cross-sectional area sx2, which is the cross-sectional area of the second largest nanostructure in the second unit group UG2, may be greater than the first largest cross-sectional area sx1, which is the cross-sectional area of the first largest nanostructure in the first unit group UG1. The third largest cross-sectional area sx3, which is the cross-sectional area of the third largest nanostructure in the third unit group UG3, may be greater than the second largest cross-sectional area sx2, which is the cross-sectional area of the second largest nanostructure in the second unit group UG2.

In an embodiment, as the distance from the center C to each of the plurality of meta-regions MA increases, a cross-sectional area sn of the smallest nanostructure in the unit group UG corresponding to the meta-region MA may decrease. For example, the second smallest cross-sectional area sn2, which is the cross-sectional area of the second smallest nanostructure in the second unit group UG2, may be less than the first smallest cross-sectional area sn1, which is the cross-sectional area of the first smallest nanostructure in the first unit group UG1. The third smallest cross-sectional area sn3, which is the cross-sectional area of the third smallest nanostructure in the third unit group UG3, may be less than the second smallest cross-sectional area sn2, which is the cross-sectional area of the second smallest nanostructure in the second unit group UG2.

FIG. 7B is a cross-sectional view of the unit group of FIG. 7A taken along line I-I′. In FIG. 7B, descriptions are made assuming that the nanostructure ns has a cylindrical shape. Repeated descriptions as those given above are omitted.

Referring to FIG. 7B, the diameter of a first largest nanostructure sxns1 in the first unit group UG1 may be a first diameter r1, and the diameter of a first smallest nanostructure snns1 may be the first diameter r1. The diameter of a second largest nanostructure sxns2 in the second unit group UG2 may be a second diameter r2, and the diameter of a second smallest nanostructure snns2 may be a fourth diameter r4. The diameter of a third largest nanostructure sxns3 in the third unit group UG3 may be a third diameter r3, and the diameter of a third smallest nanostructure snns3 may be a fifth diameter r5.

As the distance from the center C to the meta-region MA increases, the difference in diameters of the nanostructures ns in the unit group UG corresponding to the meta-region MA may increase. For example, the difference in diameters of the nanostructures ns in the second unit group UG2 may be greater than the difference in diameters of the nanostructures ns in the first unit group UG1. For example, the difference in diameters of the nanostructures ns in the third unit group UG3 may be greater than the difference in diameters of the nanostructures ns in the second unit group UG2.

In an embodiment, as the distance from the center C to each of the plurality of meta-regions MA increases, the largest diameter among the diameters of the nanostructures ns in the unit group UG corresponding to the meta-region MA may increase. As the distance from the center C to each of the plurality of meta-regions MA increases, the diameter of the largest nanostructure sxns in the unit group UG corresponding to the meta-region MA may increase. For example, the diameter of the second largest nanostructure sxns2 may be greater than the diameter of the first largest nanostructure sxns1. The second diameter r2 may be greater than the first diameter r1. For example, the diameter of the third largest nanostructure sxns3 may be greater than the diameter of the second largest nanostructure sxns2. The third diameter r3 may be greater than the second diameter r2.

In an embodiment, as the distance from the center C to each of the plurality of meta-regions MA increases, the smallest diameter among the diameters of the nanostructures ns in the unit group UG corresponding to the meta-region MA may decrease. As the distance from the center C to each of the plurality of meta-regions MA increases, the diameter of the smallest nanostructure snns in the unit group UG corresponding to the meta-region MA may decrease. For example, the diameter of the second smallest nanostructure snns2 in the second unit group UG2 may be less than the diameter of the first smallest nanostructure snns1 in the first unit group UG1. The fourth diameter r4 may be less than the first diameter r1. For example, the diameter of the third smallest nanostructure snns3 in the third unit group UG3 may be less than the diameter of the second smallest nanostructure snns2 in the second unit group UG2. The fifth diameter r5 may be less than the fourth diameter r4.

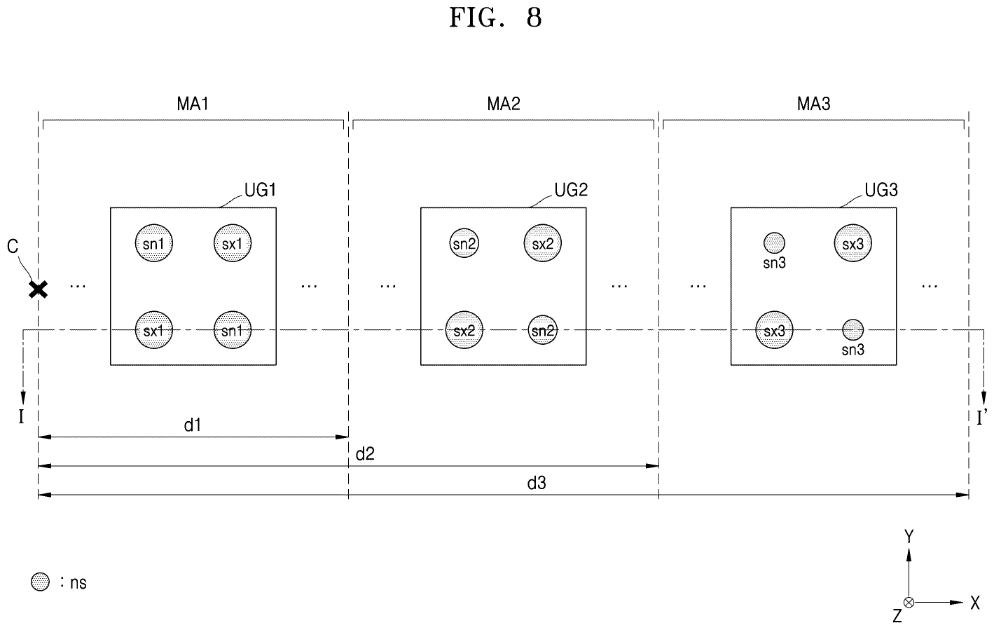

FIG. 8 is a diagram illustrating the arrangement of nanostructures according to an embodiment. Repeated descriptions as those given above are omitted.

Referring to FIG. 8, the largest nanostructures in a unit group UG may have the same cross-sectional area sx. For example, the first largest cross-sectional area sx1, the second largest cross-sectional area sx2, and the third largest cross-sectional area sx3 may have the same size. When the nanostructures ns include cylinders, the nanostructures ns in each of the unit groups UG may have the same largest diameter.

As the distance from the center C to each of the plurality of meta-regions MA increases, a cross-sectional area sn of the smallest nanostructure in the unit group UG corresponding to the meta-region MA may decrease. For example, a second smallest cross-sectional area sn2 may be less than a first smallest cross-sectional area sn1. A third smallest cross-sectional area sn3 may be less than the second smallest cross-sectional area sn2. As the distance from the center C to each of the plurality of meta-regions MA increases, the smallest diameter among the diameters of the nanostructures ns in the unit group UG corresponding to the meta-region MA may decrease.

As the distance from the center C to each of the plurality of meta-regions MA increases, the cross-sectional area sn of the smallest nanostructure in the unit group UG corresponding to the meta-region MA decreases. Therefore, even if the largest cross-sectional areas of the nanostructures ns in the unit group UG have the same size, the difference in the cross-sectional areas of the nanostructures ns in the unit group UG may increase.

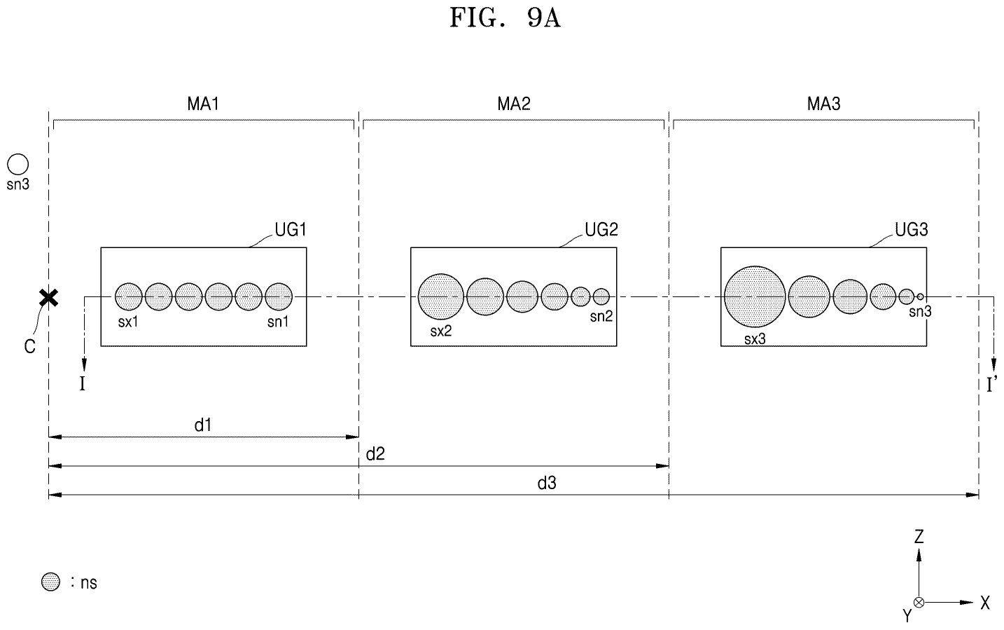

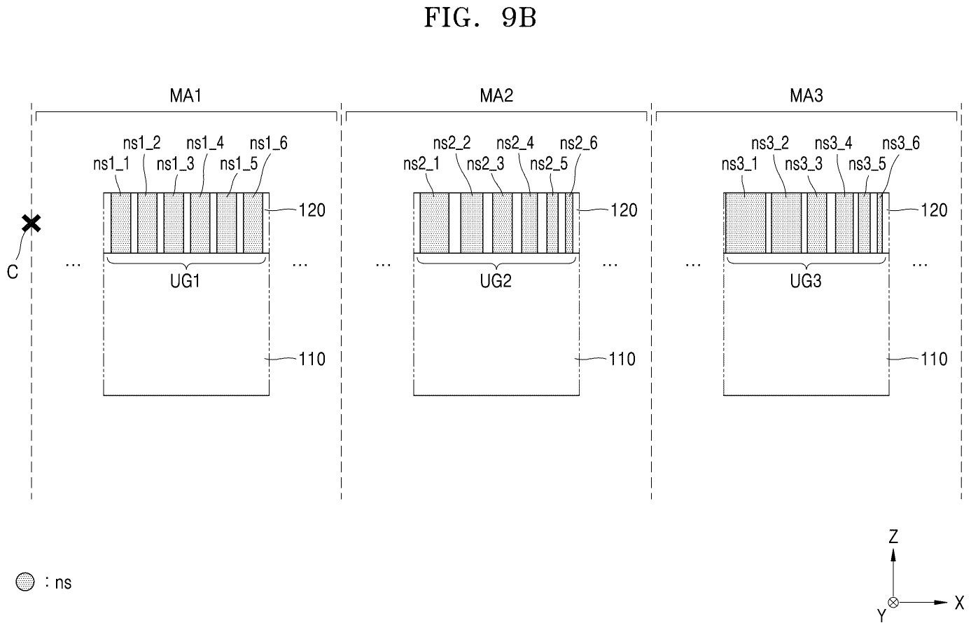

FIG. 9A is a diagram showing an example in which nanostructures according to an embodiment are gradually arranged according to the sizes of cross-sectional areas thereof. Repeated descriptions as those given above are omitted.

Referring to FIG. 9A, a single unit group UG may include six nanostructures ns. However, this is only one example, and the single unit group UG may include two or more nanostructures ns.

In an embodiment, the nanostructures ns in each of the unit groups UG may have cross-sectional areas that increase at a constant rate in a range from a cross-sectional area sn of the smallest nanostructure to a cross-sectional area sx of the largest nanostructure. The first unit group UG1 may include the nanostructures ns having the same cross-sectional area. A first largest cross-sectional area sx1 may be equal to a first smallest cross-sectional area sn1.

For example, the second unit group UG2 may include a nanostructure ns having a second largest cross-sectional area sx2 and a nanostructure ns having a second smallest cross-sectional area sn2. The six nanostructures ns in the second unit group UG2 may have cross-sectional areas that increase at a constant rate in a range from the second smallest cross-sectional area sn2 to the second largest cross-sectional area sx2. The second largest cross-sectional area sx2 may be greater than the first largest cross-sectional area sx1, and the second smallest cross-sectional area sn2 may be less than the first smallest cross-sectional area sn1. However, the embodiment is not necessarily limited thereto.

For example, the third unit group UG3 may include a nanostructure ns having a third largest cross-sectional area sx3 and a nanostructure ns having a third smallest cross-sectional area sn3. The six nanostructures ns in the third unit group UG3 may have cross-sectional areas that increase at a constant rate in a range from the third smallest cross-sectional area sn3 to the third largest cross-sectional area sx3. The third largest cross-sectional area sx3 may be greater than the second largest cross-sectional area sx2, and the third smallest cross-sectional area sn3 may be less than the second smallest cross-sectional area sn2. However, the embodiment is not necessarily limited thereto.

In an embodiment, the nanostructures ns may be arranged, gradually according to the sizes of the cross-sectional areas thereof, inside the single unit group UG. For example, in the second unit group UG2, the nanostructures ns may be arranged such that the cross-sectional areas of the nanostructures ns decrease from the second largest cross-sectional area sx2 to the second smallest cross-sectional area sn2 in the direction from the center C toward the second meta-region MA2. However, the embodiment is not necessarily limited thereto. In the second unit group UG2, the nanostructures ns may also be arranged such that the cross-sectional areas of the nanostructures ns increase from the second smallest cross-sectional area sn2 to the second largest cross-sectional area sx2 in the direction from the center C toward the second meta-region MA2.

For example, in the third unit group UG3, the nanostructures ns may be arranged such that the cross-sectional areas of the nanostructures ns decrease from the third largest cross-sectional area sx3 to the third smallest cross-sectional area sn3 in the direction from the center C toward the third meta-region MA3. However, the embodiment is not necessarily limited thereto. In the third unit group UG3, the nanostructures ns may be arranged such that the cross-sectional areas of the nanostructures ns increase from the third smallest cross-sectional area sn3 to the third largest cross-sectional area sx3 in the direction from the center C toward the third meta-region MA3.

FIG. 9B is a cross-sectional view of the unit group of FIG. 9A taken along line I-I′. In FIG. 9B, descriptions are made assuming that the nanostructure ns has a cylindrical shape. Repeated descriptions as those given above are omitted.

Referring to FIG. 9B, a first unit group UG1 may include six first nanostructures ns1_1 to ns1_6, a second unit group UG2 may include six second nanostructures ns2_1 to ns2_6, and a third unit group UG3 may include six third nanostructures ns3_1 to ns3_6.

As the distance from the center C to the meta-region MA increases, the difference in diameters of the nanostructures ns in the unit group UG corresponding to the meta-region MA may increase. As the distance from the center C to each of the plurality of meta-regions MA increases, the difference between the largest diameter and smallest diameter of the nanostructures ns in the unit group UG corresponding to the meta-region MA may increase. For example, the first unit group UG1 may include the first nanostructures ns1_1 to ns1_6 having the same diameter. Among the second nanostructures ns2_1 to ns2_6 in the second unit group UG2, the second nanostructure ns2_1 may have a largest diameter, and the second nanostructure ns2_6 may have a smallest diameter. The difference in diameters between the second nanostructure ns2_1 and the second nanostructure ns2_6 may be greater than the difference in diameters between the first nanostructure ns1_1 and the first nanostructure ns1_6. For example, among the third nanostructures ns3_1 to ns3_6 in the third unit group UG3, the third nanostructure ns3_1 may have a largest diameter, and the third nanostructure ns3_6 may have a smallest diameter. The difference in diameters between the third nanostructure ns3_1 and the third nanostructure ns3_6 may be greater than the difference in diameters between the second nanostructure ns2_1 and the second nanostructure ns2_6.

In an embodiment, the nanostructures ns in the unit group UG may be arranged in order of the diameters thereof. For example, the nanostructures ns may be arranged in the order in which the diameters of the nanostructures ns decrease in the unit group UG. For example, in the second unit group UG2, the second nanostructure ns2_1, the second nanostructure ns2_2, the second nanostructure ns2_3, the second nanostructure ns2_4, the second nanostructure ns2_5, and the second nanostructure ns2_6 may be arranged in this order in the direction from the center C toward the second meta-region MA2. The diameters of the second nanostructure ns2_1, the second nanostructure ns2_2, the second nanostructure ns2_3, the second nanostructure ns2_4, the second nanostructure ns2_5, and the second nanostructure ns2_6 may decrease in this order.

Also, for example, in the third unit group UG3, the third nanostructure ns3_1, the third nanostructure ns3_2, the third nanostructure ns3_3, the third nanostructure ns3_4, the third nanostructure ns3_5, and the third nanostructure ns3_6 may be arranged in this order in the direction from the center C toward the third meta-region MA3. The diameters of the third nanostructure ns3_1, the third nanostructure ns3_2, the third nanostructure ns3_3, the third nanostructure ns3_4, the third nanostructure ns3_5, and the third nanostructure ns3_6 may decrease in this order. However, the embodiment is not necessarily limited thereto, and the nanostructures ns may be arranged in the order in which the diameters of the nanostructures ns increase in the unit group UG.

In an embodiment, the differences in diameters between adjacent nanostructures ns in a single unit group UG may be constant. For example, in the second unit group UG2, the difference in diameters between the second nanostructure ns2_1 and the second nanostructure ns2_2 may be the same as the difference in diameters between the second nanostructure ns2_3 and the second nanostructure ns2_4. The difference in diameters between the second nanostructure ns2_3 and the second nanostructure ns2_4 may be the same as the difference in diameters between the second nanostructure ns2_5 and the second nanostructure ns2_6.

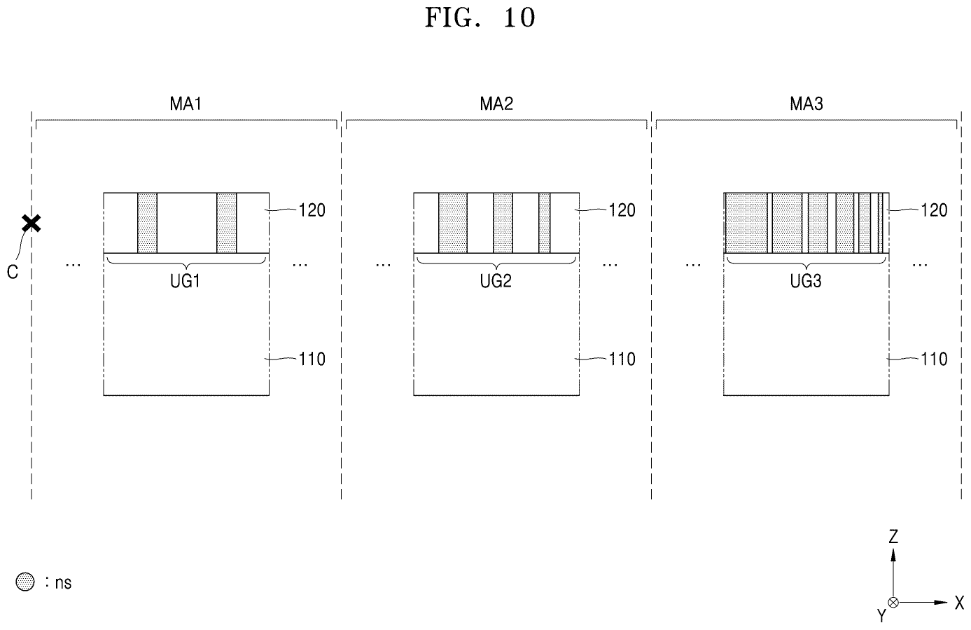

FIG. 10 is a diagram showing an example in which different numbers of nanostructures according to an embodiment are arranged in unit groups. Repeated descriptions as those given above are omitted.

Referring to FIG. 10, unit groups UG may include different numbers of nanostructures ns. In an embodiment, as the distance from the center C to each of the plurality of meta-regions MA increases, the number of the nanostructures ns in the unit group UG corresponding to the meta-region MA may increase. For example, a first meta-region MA1 may include two nanostructures ns, a second meta-region MA2 may include three nanostructures ns, and a third meta-region MA3 may include six nanostructures ns. However, the number of nanostructures ns in each of the meta-regions MA is not necessarily limited thereto.

As the distance from the center C to each of the plurality of meta-regions MA increases, the number of nanostructures ns in the unit group UG corresponding to the meta-region MA may increase, and the difference in the cross-sectional areas between the largest nanostructure and the smallest nanostructure among the nanostructures ns in the unit group UG corresponding to the meta-region MA may increase.

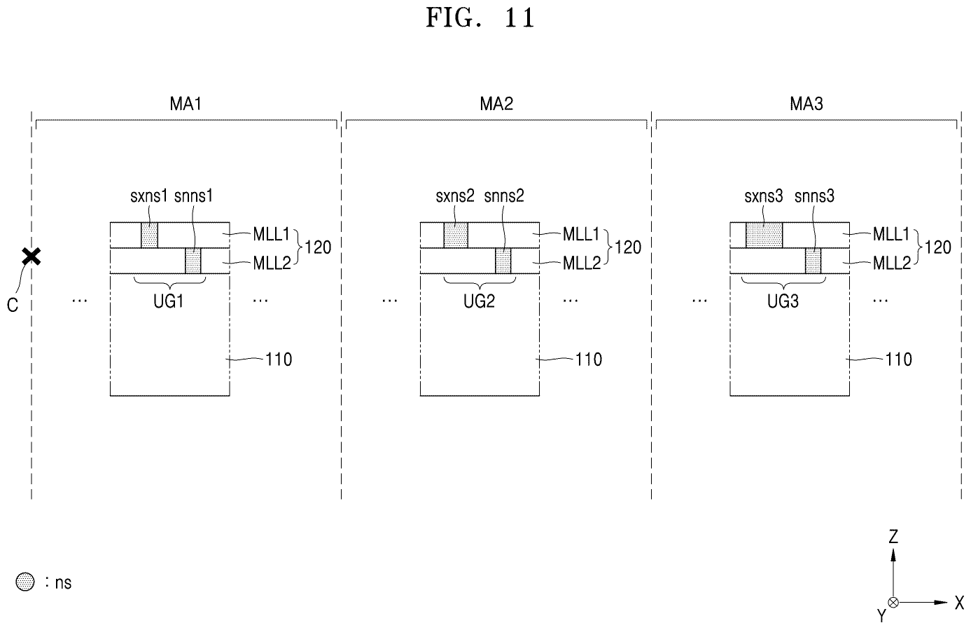

FIG. 11 is a diagram illustrating a meta-lens layer including a plurality of layers, according to an embodiment. Repeated descriptions as those given above are omitted.

Referring to FIG. 11, the meta-lens layer 120 may include a first meta-lens layer MLL1 and a second meta-lens layer MLL2. The first meta-lens layer MLL1 may be disposed on the second meta-lens layer MLL2 in the Z direction. At least one of the first meta-lens layer MLL1 and the second meta-lens layer MLL2 may include a nanostructure ns. A unit group UG may include at least two nanostructures ns, and the nanostructures ns in the single unit group UG may be arranged in at least one of the first meta-lens layer MLL1 and the second meta-lens layer MLL2.

For example, the nanostructures ns in the single unit group UG may be provided in the first meta-lens layer MLL1 and the second meta-lens layer MLL2. For example, in a first unit group UG1, a first largest nanostructure sxns1 may be arranged in the first meta-lens layer MLL1, and a first smallest nanostructure snns1 may be arranged in the second meta-lens layer MLL2. In a second unit group UG2, a second largest nanostructure sxns2 may be arranged in the first meta-lens layer MLL1, and a second smallest nanostructure snns2 may be arranged in the second meta-lens layer MLL2. In a third unit group UG3, a third largest nanostructure sxns3 may be arranged in the first meta-lens layer MLL1, and a third smallest nanostructure snns3 may be arranged in the second meta-lens layer MLL2. However, this is only one example, and the nanostructures ns may be arranged in the meta-lens layer 120 in various configurations.

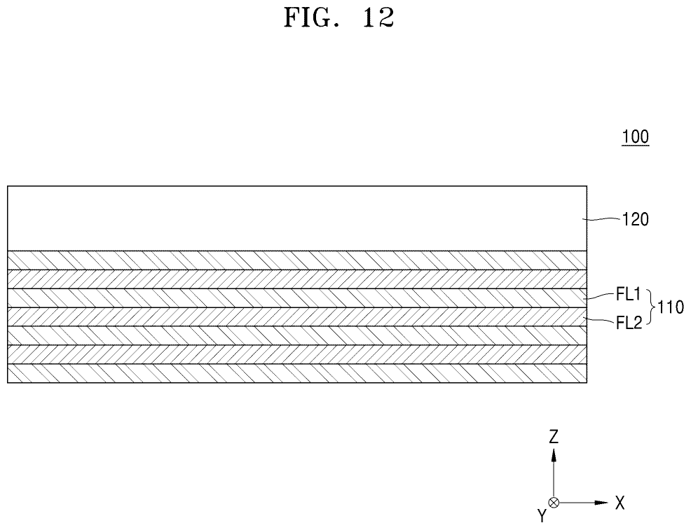

FIG. 12 is a diagram illustrating an infrared filter 110 according to an embodiment.

Referring to FIG. 12, an optical filter device 100 may include the infrared filter 110 and a meta-lens layer 120. The infrared filter 110 may include a first filter layer FL1 and a second filter layer FL2. The first filter layer FL1 may include a material layer having a first refractive index, and the second filter layer FL2 may include a material layer having a second refractive index. The first refractive index may be different from the second refractive index. For example, the first refractive index may be greater than the second refractive index. However, the embodiment is not necessarily limited thereto, and the first refractive index may be less than the second refractive index.

In the embodiment, the infrared filter 110 may have a structure in which the first filter layer FL1 and the second filter layer FL2 are alternately stacked on each other. For example, SiN, Si, TiO, GaAs, GaP, GaN, or the like may be used as the first filter layer FL1, and SiO₂, SOG, SU-8, or the like may be used as the second filter layer FL2. However, the embodiment is not necessarily limited thereto. The thickness of the first filter layer FL1 may be the same as or different from the thickness of the second filter layer FL2.

FIG. 13 is a diagram illustrating an image sensor 10 including an optical filter device 100 according to an embodiment. A meta-lens layer 120 and an infrared filter 110 of FIG. 13 correspond to the meta-lens layer 120 and the infrared filter 110, respectively, described with reference to FIGS. 1 to 12, and thus, repeated descriptions thereof are omitted.

Referring to FIG. 13, the image sensor 10 may include the optical filter device 100 and an optical device 200, and the optical filter device 100 may include the meta-lens layer 120 and the infrared filter 110. The optical device 200 may include a light-collecting lens layer 210, a color filter 220, and a pixel array 230. In an embodiment, the optical filter device 100 and the optical device 200 may be formed integrally with each other and provided in the image sensor 10.

A lens assembly 20 may focus an image of an object outside a camera module onto the image sensor 10. More specifically, the lens assembly 20 serves to focus on the pixel array 230 of the image sensor 10. Although FIG. 13 schematically shows a single lens for convenience of illustration, an actual lens assembly 20 may include a plurality of lenses.

The image sensor 10 may convert an optical signal of an object incident through an optical lens into image data. The image sensor 10 may include, for example, a charge coupled device (CCD) image sensor or a complementary metal oxide semiconductor (CMOS) image sensor.

The image sensor 10 may be mounted on electronic equipment having an image or light sensing function. For example, the electronic equipment may be provided as personal computers (PCs), Internet of Things (IoT) device, or portable electronic devices. The portable electronic devices may include laptop computers, mobile phones, smartphones, tablet PCs, personal digital assistants (PDAs), enterprise digital assistants (EDAs), digital still cameras, digital video cameras, audio devices, portable multimedia players (PMPs), personal navigation devices (PNDs), MP3 players, handheld game consoles, e-books, wearable devices, and the like. In addition, the image sensor 10 may be mounted on electronic equipment, such as drones and advanced drivers assistance systems (ADASs), or electronic equipment provided as components in vehicles, furniture, manufacturing equipment, doors, other measuring devices, etc.

The image sensor 10 may convert an optical image formed by the lens assembly 20 into an electrical signal. The light passing through the lens assembly 20 may be transmitted to the optical filter device 100 and the optical device 200. The light passing through the lens assembly 20 may reach the meta-lens layer 120. The flow of incident light may be controlled based on nanostructures arranged in the meta-lens layer 120. The nanostructures may be arranged to mitigate differences in the transmission characteristics of light passing through the infrared filter 110 depending on the angle of incidence.

The nanostructures may be arranged such that, as a distance from the center of the meta-lens layer 120 increases, the difference in cross-sectional areas of the nanostructures in the meta-region corresponding to the distance therefrom increases. The light incident on the meta-lens layer 120 may be refracted due to the difference in cross-sectional areas of the nanostructures ns. At least a portion of the light passing through the meta-lens layer 120 may pass through the infrared filter 110.

The optical device 200 converts an optical image of an object OBJ formed by the optical filter device 100 into an electrical signal. The optical device 200 may include the light-collecting lens layer 210, the color filter 220, and the pixel array 230.

The pixel array 230 may include a plurality of pixels. Each of the plurality of pixels may sense light of a specific spectral range from the light received through the light-collecting lens layer 210. The pixel array 230 may include a plurality of row lines, a plurality of column lines, and a plurality of pixels connected to the plurality of row lines and the plurality of column lines and arranged in rows and columns. In an embodiment, the plurality of pixels may include active pixel sensors (APS). The pixel array 230 may include the plurality of pixels that sense light of different wavelengths. The pixels may be arranged in many different manners.

Each of the plurality of pixels may include at least one photoelectric conversion element, and the pixel may sense light using the photoelectric conversion element and output an image signal including an electrical signal according to the sensed light. For example, the photoelectric conversion element may include a light-sensitive element including an organic or inorganic material, such as an inorganic photodiode, an organic photodiode, a perovskite photodiode, a phototransistor, a photogate, and a pinned photodiode. In an embodiment, each of the plurality of pixels may include the plurality of photoelectric conversion elements.

The color filter 220 may be disposed on the pixel array 230. The color filter 220 may allow light in a specific spectral range to be transmitted therethrough. The color filter 220 may allow light in a visible ray range to be transmitted therethrough. Depending on the type of color filter 220 disposed above each of the plurality of pixels, the type of light sensed by the pixel may be determined.

When the color filter 220 for transmitting light in a visible ray range is disposed above a specific pixel in the pixel array 230, the specific pixel may sense light in the visible ray range and convert the light in the visible ray range into an electric signal. Depending on the color filter 220 disposed above the specific pixel, the color sensed by the pixel may be determined. However, the embodiment is not limited thereto. In a specific photodiode, light of a specific wavelength band may be converted into an electrical signal depending on the level of the electrical signal applied to the photoelectric conversion element.

The color filter 220 may include a red color filter, a green color filter, and a blue color filter. However, the embodiment is not limited thereto. The color filter 220 may include color filters 220 that transmit light in spectral ranges other than red, green, and blue. For example, the color filter 220 may include color filters 220 for sensing yellow, cyan, and magenta colors.

The light-collecting lens layer 210 may be disposed on the color filter 220. The light-collecting lens layer 210 may be disposed below the optical filter device 100. The light-collecting lens layer 210 may focus light onto the pixel array 230. Each of the plurality of pixels in the pixel array 230 may sense light of a specific spectral range from light received through the light-collecting lens layer 210. For example, the pixel array 230 may include a red pixel for converting light in the red spectral range into an electric signal, a green pixel for converting light in the green spectral range into an electric signal, and a blue pixel for converting light in the blue spectral range into an electric signal. However, the embodiment is not limited thereto. The pixel array 230 may include pixels that convert light in spectral ranges other than red, green, and blue into an electric signal.

The optical filter device 100 and the optical device 200 may be formed integrally with each other and provided in the image sensor 10, and thus, the total length of the image sensor 10 may be reduced. In addition, the image sensor 10 may include the meta-lens layer 120 in which nanostructures are arranged such that the difference in cross-sectional areas of the nanostructures in the unit group varies depending on the distance from the center of the meta-lens layer 120. Accordingly, the differences in sensitivities of pixels depending on the angle of incidence may be reduced, and the differences in pixel signals over the entire region of the pixel array 230 may be reduced. Accordingly, the total length of the image sensor 10 may be reduced and the performance thereof may be improved.

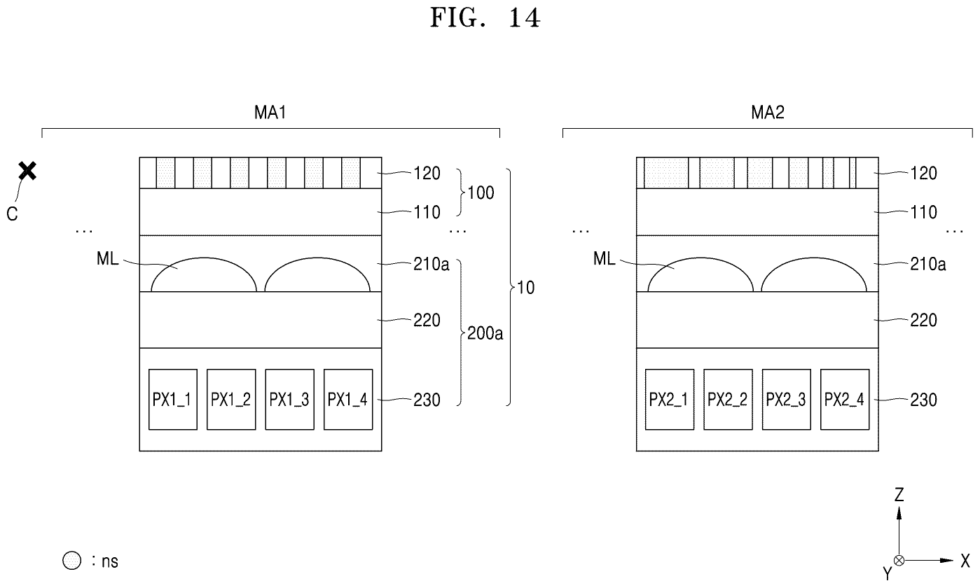

FIG. 14 is a cross-sectional view of an image sensor 10 according to an embodiment. A light-collecting lens layer 210a of FIG. 14 may correspond to the light-collecting lens layer 210 of FIG. 13. In FIG. 14, the light-collecting lens layer 210a may include a micro lens array. The micro lens array may include a plurality of micro lenses ML. Repeated descriptions as those given above are omitted.

Referring to FIG. 14, the image sensor 10 may include a pixel array 230, a color filter 220, a light-collecting lens layer 210a, an infrared filter 110, and a meta-lens layer 120. In an embodiment, the color filter 220 may be disposed on the pixel array 230, the light-collecting lens layer 210a may be disposed on the color filter 220, and the optical filter device 100 may be disposed on the light-collecting lens layer 210a. However, the arrangement configuration of the image sensor 10 is not necessarily limited thereto.

The pixel array 230 may include a plurality of pixels PX. In FIG. 14, a pixel PX1 and a pixel PX2 may represent any pixel in the pixel array 230. For example, a pixel PX1_1, a pixel PX1_2, a pixel PX1_3, and a pixel PX1_4 (or referred to as first to fourth pixels PX1_1, PX1_2, PX1_3, and PX1_4) may be arranged in an X direction, as illustrated in FIG. 14.

In an embodiment, the number of pixels PX of the pixel array 230 corresponding to each of meta-regions MA may vary. For example, the number of pixels PX of the pixel array 230 corresponding to a first meta-region MA1 may be four. The first meta-region MA1 may correspond to the first pixel PX1_1, the second pixel PX1_2, the third pixel PX1_3, and the fourth pixel PX1_4. For example, the number of pixels PX of the pixel array 230 corresponding to a second meta-region MA2 may be four. The second meta-region MA2 may correspond to a first pixel PX2_1, a second pixel PX2_2, a third pixel PX2_3, and a fourth pixel PX2_4. However, although FIG. 14 illustrates that the number of pixels PX corresponding to the meta-region MA is four, the embodiment is not necessarily limited thereto.

The color filter 220 may include a plurality of filters that transmit only light of a specific wavelength band and absorb or reflect light of other wavelength bands. For example, the color filter 220 may include a green filter disposed above the pixel PX1_1 and the pixel PX1_2 and transmitting only light of a first wavelength band and a red filter disposed above the pixel PX1_3 and the pixel PX1_4 and transmitting only light of a second wavelength band that is different from the first wavelength band. However, the color of the color filter 220 and the number of pixels arranged in the color filter 220 are not necessarily limited thereto.

In an embodiment, the light-collecting lens layer 210a may include a micro lens array. The micro lens array may include a plurality of micro lenses ML. The micro lenses ML may focus light. For example, the micro lens ML may focus light passing through the optical filter device 100 onto the pixel PX.

The micro lens ML for focusing light may be disposed above each of the plurality of pixels PX or above each of pixel groups including adjacent pixels PX. For example, the micro lens ML may be disposed above the first pixel PX1_1 and the first pixel PX1_2, and the micro lens ML may be disposed above the first pixel PX1_3 and the first pixel PX1_4. Although FIG. 14 illustrates that one micro lens ML is provided per two pixels PX, the embodiment is not necessarily limited thereto. Each of the plurality of pixels PX may sense light of a specific spectral range from the light received through the micro lens ML. In an embodiment, a region other than the micro lenses ML in the light-collecting lens layer 210a may include a material having a lower refractive index than the micro lenses ML. For example, the region other than the micro lenses ML in the light-collecting lens layer 210a may include SiO₂, air, siloxane-based spin on glass (SOG), etc. However, the embodiment is not necessarily limited thereto.

Nanostructures ns may be arranged such that, as the distance from a center C to a meta-region MA increases, the difference in cross-sectional areas of the nanostructures ns in a unit group UG corresponding to the meta-region MA increases. As the distance from the center C to the meta-region MA increases, a difference in cross-sectional areas between the largest nanostructure and the smallest nanostructure among the nanostructures ns in the unit group UG corresponding to the meta-region MA may increase. The light passing through the meta-lens layer 120 and the infrared filter 110 may reach the micro lens ML.

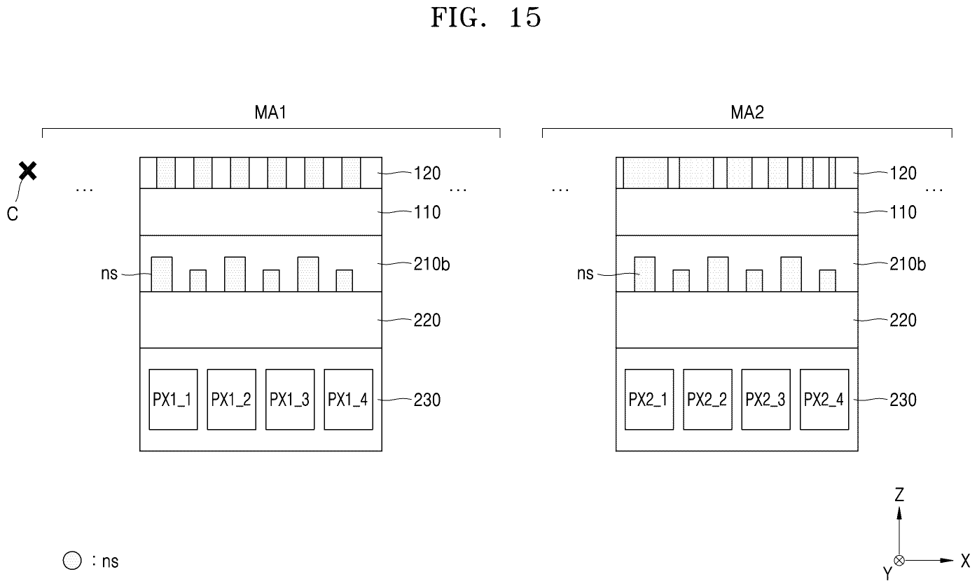

FIG. 15 is a cross-sectional view of an image sensor according to an embodiment. A light-collecting lens layer 210b of FIG. 15 may correspond to the light-collecting lens layer 210 of FIG. 13. In FIG. 15, the light-collecting lens layer 210b may include at least one nanostructure ns. The light-collecting lens layer 210b may include a micro lens array. The micro lens array may include a plurality of nanostructures ns. Repeated descriptions as those given above with reference to FIG. 14 are omitted.

Referring to FIG. 15, the image sensor 10 may include a pixel array 230, a color filter 220, a light-collecting lens layer 210b, an infrared filter 110, and a meta-lens layer 120. In an embodiment, the light-collecting lens layer 210b may include at least one nanostructure ns. The light-collecting lens layer 210b may include at least one nanostructure ns that focuses light onto the pixel PX. For example, the nanostructure ns may focus light passing through the optical filter device 100 onto the pixel PX. The light-collecting lens layer 210b including the nanostructures ns may also be referred to as a nano-optical micro lens array, a meta-surface lens array, or the like.

The nanostructures ns for focusing light may be arranged above the pixel array 230. The nanostructure ns of the light-collecting lens layer 210b may include a material that is the same as or different from that of a nanostructure ns of the meta-lens layer 120. In the light-collecting lens layer 210b, the nanostructures ns may be arranged in various configurations. For example, nanostructures ns having different sizes may be arranged in the light-collecting lens layer 210b. Also, nanostructures ns having different heights may be arranged in the light-collecting lens layer 210b. Each of the plurality of pixels PX may sense light of a specific spectral range from the light received through the nanostructures ns of the light-collecting lens layer 210b. In an embodiment, a region other than the nanostructures ns in the light-collecting lens layer 210b may include a material having a lower refractive index than the nanostructures ns. For example, the region other than the nanostructures ns in the light-collecting lens layer 210b may include SiO₂, air, siloxane-based spin on glass (SOG), etc. However, the embodiment is not necessarily limited thereto.

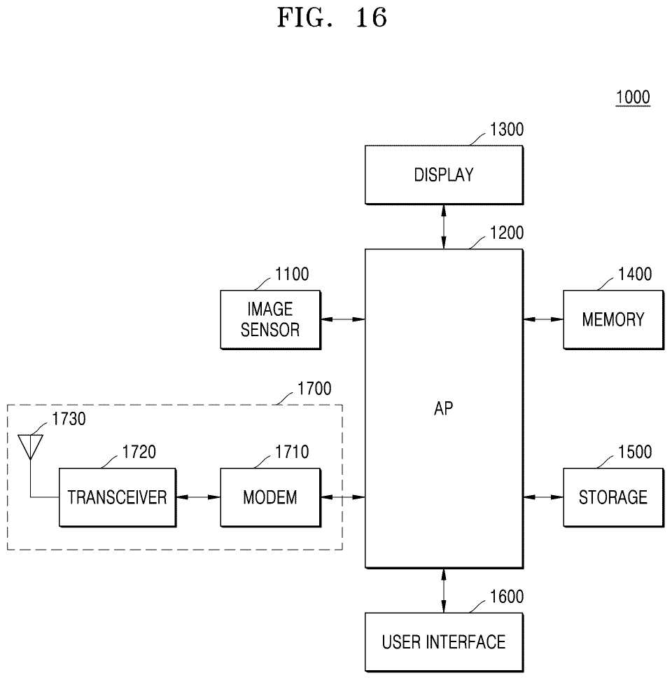

FIG. 16 is a block diagram showing an electronic device 1000 according to an embodiment. For example, the electronic device 1000 may include a portable terminal.

Referring to FIG. 16, the electronic device 1000 according to an embodiment may include an application processor 1200, an image sensor 1100, a display device 1300, memory 1400, a storage 1500, a user interface 1600, and a wireless transceiver 1700. The description of the image sensor according to embodiments described above with reference to FIGS. 13 to 16 may be applied to the image sensor 1100.

The image sensor 1100 may include a meta-lens layer. The nanostructures may be arranged such that, as a distance from the center of the meta-lens layer increases, the difference in cross-sectional areas of the nanostructures in the meta-region corresponding to the distance therefrom increases. The light incident on the meta-lens layer may be refracted due to the difference in cross-sectional areas of the nanostructures. At least a portion of the light passing through the meta-lens layer may pass through the infrared filter. Since the meta-lens layer is provided in the image sensor 1100, the total length of the image sensor 1100 may be reduced and the performance of the image sensor 1100 may be improved.

The application processor 1200 may control all operations of the electronic device 1000 and may be provided as a system on chip (SoC) that runs application programs, an operating system, etc.

The application processor 1200 may receive output data from the image sensor 1100.

The image sensor 1100 may generate data, for example, image data, based on the received optical signal and provide the image data to the application processor 1200. The image data may also be referred to as pixel values. The image sensor 1100 may generate image data with reduced lens shading phenomenon.

The memory 1400 may be provided as volatile memory, such as dynamic random-access memory (DRAM) and static random-access memory (SRAM), or non-volatile resistive memory, such as ferroelectric random-access memory (FeRAM), resistive random-access memory (RRAM), and phase-change random-access memory (PRAM). The memory 1400 may store programs and/or data processed or executed by the application processor 1200.

The storage 1500 may be provided as non-volatile memory devices, such as NOT-AND (NAND) flash and resistive memory. For example, the storage 1500 may be provided as a memory card (a multimedia card (MMC), an embedded MMC (eMMC), secure digital (SD), and micro SD), etc. The storage 1500 may store data and/or programs for executing algorithms that control an image processing operation of the image sensor 1100. Also, when the image processing operation is performed, the data and/or programs may be loaded into the memory 1400. In an embodiment, the storage 1500 may store output image data, generated from the image sensor 1100, such as corrected image data and post-processed image data.

The user interface 1600 may be provided as various devices, capable of receiving a user input, such as a keyboard, a curtain key panel, a touch panel, a fingerprint sensor, and a microphone. The user interface 1600 may receive a user input and provide the application processor 1200 with a signal corresponding to the received user input.

The wireless transceiver 1700 may include a transceiver 1720, a modem 1710, and an antenna 1730.

While aspects of the inventive concept have been particularly shown and described with reference to embodiments thereof, it will be understood that various changes in form and details may be made therein without departing from the spirit and scope of the following claims.

What is claimed is:

1. An optical filter device comprising:
a meta-lens layer comprising a plurality of nanostructures; and
an infrared filter configured to block light belonging to an infrared wavelength range among light passing through the meta-lens layer,
wherein the meta-lens layer comprises a plurality of meta-regions distinguished according to distance from a center of the meta-lens layer,
the plurality of meta-regions comprise unit groups corresponding to the plurality of meta-regions, respectively, and each of the unit groups comprises at least two nanostructures, and
wherein, as the distance from the center of the meta-lens layer to each of the plurality of meta-regions increases, a difference in cross-sectional areas between a largest nanostructure having a largest cross-sectional area and a smallest nanostructure having a smallest cross-sectional area, among the at least two nanostructures in the unit group corresponding to the meta-region, increases.

2. The optical filter device of claim 1, wherein, as the distance from the center of the meta-lens layer to each of the plurality of meta-regions increases, the cross-sectional area of the largest nanostructure in the unit group corresponding to the meta-region increases.

3. The optical filter device of claim 1, wherein, as the distance from the center of the meta-lens layer to each of the plurality of meta-regions increases, the cross-sectional area of the smallest nanostructure in the unit group corresponding to the meta-region decreases.

4. The optical filter device of claim 1, wherein the unit groups corresponding to the plurality of meta-regions, respectively, are repeatedly arranged inside the corresponding meta-region.

5. The optical filter device of claim 1, wherein the plurality of meta-regions comprises a central region comprising the center of the meta-lens layer, and
the nanostructures in the unit group corresponding to the central region of the meta-lens layer have the same cross-sectional area.

6. The optical filter device of claim 1, wherein the largest nanostructures in the unit groups have the same cross-sectional area.

7. The optical filter device of claim 1, wherein the nanostructures in each of the unit groups have cross-sectional areas increasing at a constant rate in a range from the cross-sectional area of the smallest nanostructure to the cross-sectional area of the largest nanostructure, and
the nanostructures are gradually arranged inside the unit group according to sizes of the cross-sectional areas of the nanostructures.

8. The optical filter device of claim 1, wherein the infrared filter comprises a first filter layer having a first refractive index and a second filter layer having a second refractive index, and
the first refractive index is different from the second refractive index.

9. The optical filter device of claim 1, wherein, as the distance from the center of the meta-lens layer to each of the plurality of meta-regions increases, the number of nanostructures in the unit group corresponding to the meta-region increases.

10. The optical filter device of claim 1, wherein the plurality of meta-regions are distinguished based on a chief ray angle (CRA) value.

11. An image sensor comprising:
a pixel array in which a plurality of pixels are arranged;
a color filter disposed on the pixel array;
a light-collecting lens layer disposed on the color filter and configured to focus light onto the pixel array;
an infrared filter disposed on the light-collecting lens layer and configured to block light in an infrared wavelength range; and
a meta-lens layer comprising a plurality of nanostructures,
wherein the meta-lens layer comprises unit groups corresponding to distances from a center of the meta-lens layer, and each of the unit groups comprises a plurality of nanostructures, and
wherein, as a distance from the center of the meta-lens layer increases, a difference in cross-sectional areas of the nanostructures in the unit groups corresponding to distances from the center of the meta-lens layer increases.

12. The image sensor of claim 11, wherein, as a distance from the center of the meta-lens layer increases, a largest cross-sectional area among cross-sectional areas of the nanostructures in the unit groups corresponding to distances from the center of the meta-lens layer increases.

13. The image sensor of claim 11, wherein, as a distance from the center of the meta-lens layer increases, a smallest cross-sectional area among cross-sectional areas of the nanostructures in the unit groups corresponding to distances from the center of the meta-lens layer decreases.

14. The image sensor of claim 11, wherein the light-collecting lens layer comprises at least one nanostructure configured to focus light onto the pixel array.

15. The image sensor of claim 11, wherein the light-collecting lens layer comprises a micro lens array.

16. An optical filter device comprising:
a meta-lens layer comprising a first meta-region and a second meta-region; and
an infrared filter configured to block light belonging to an infrared wavelength range among light passing through the meta-lens layer,
wherein a distance from a center of the meta-lens layer to the second meta-region is greater than a distance from the center of the meta-lens layer to the first meta-region,
the first meta-region comprises a first unit group, including a plurality of nanostructures, repeatedly arranged in the first meta-region,
the second meta-region comprises a second unit group, including a plurality of nanostructures, repeatedly arranged in the second meta-region, and
a difference in diameters of the plurality of nanostructures in the second unit group is greater than a difference in diameters of the plurality of nanostructures in the first unit group.

17. The optical filter device of claim 16, wherein the first meta-region comprises the center of the meta-lens layer, and
the plurality of nanostructures in the first unit group have the same diameter.

18. The optical filter device of claim 16, wherein the plurality of nanostructures in the second unit group are arranged in order of the diameters of the plurality of nanostructures in the second unit group, and
a difference in diameters between adjacent nanostructures in the second unit group is constant.

19. The optical filter device of claim 16, wherein the number of the plurality of nanostructures in the first unit group is equal to the number of the plurality of nanostructures in the second unit group, and
a largest diameter among the diameters of the plurality of nanostructures in the second unit group is greater than a largest diameter among the diameters of the plurality of nanostructures in the first unit group.

20. The optical filter device of claim 16, wherein the number of the plurality of nanostructures in the first unit group is equal to the number of the plurality of nanostructures in the second unit group, and
a smallest diameter among the diameters of the plurality of nanostructures in the second unit group is less than a smallest diameter among the diameters of the plurality of nanostructures in the first unit group.
